(19) United States
(12) Patent Application Publication
(10) Pub. No.: US 2026/0047194 A1
(43) Pub. Date: Feb. 12, 2026

(54) HYBRID NANOSTRUCTURE DEVICE AND METHODS OF FORMING THE SAME

(71) Applicant: Taiwan Semiconductor Manufacturing Co., Ltd., Hsinchu (TW)

(72) Inventors: Jen-Hsiang Lu, Taipei City (TW); Feng-Ming Chang, Taitung City (TW); Kao-Ting Lai, Hsinchu (TW)

(21) Appl. No.: 18/799,232

(22) Filed: Aug. 9, 2024

(51) Int. Cl. H01L 27/092; H01L 21/8238; H01L 29/06; H01L 29/423; H01L 29/66; H01L 29/775; H01L 29/786

(52) U.S. Cl. CPC H10D 84/85; H10D 30/014; H10D 30/43; H10D 30/6735; H10D 30/6757; H10D 62/121; H10D 64/017; H10D 84/0188; H10D 84/038

(57) ABSTRACT

A device includes a first semiconductor fin and a second semiconductor fin; a first nanostructure over the first semiconductor fin; a second nanostructure over the second semiconductor fin; a dummy region extending between the first semiconductor fin and a bottom surface of the first nanostructure; and a gate structure on a top surface of the first nanostructure, on a top surface of the second nanostructure, and extending between the second semiconductor fin and a bottom surface of the second nanostructure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2, 3, 4, 5, 6, 7, 8, 9A, 9B, 10A, 10B, 10C, 11A, 11B, 11C, 12A, 12B, 12C, 13A, 13B, 14A, 14B, 15A, 15B, 16A, 16B, 17A, 17B, 18A, 18B, 18C, 18D, 19A, 19B, 20A, 20B, 21A, 21B, 22A, 22B, 23A, and 23B are cross-sectional views of intermediate stages in the manufacturing of nanostructure-FETs, in accordance with some embodiments.

FIG. 24 illustrates a detailed view of an intermediate stage in the manufacturing of nanostructure-FETs, in accordance with some embodiments.

FIGS. 25A, 25B, 25C, 26A, 26B, and 26C are cross-sectional views of intermediate stages in the manufacturing of nanostructure-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nanostructure field-effect transistors (e.g., “nanostructure-FETs” or “nano-FETs”). Various embodiments may be applied, however, to dies comprising other types of transistors (e.g., fin field-effect transistors (FinFETs), planar transistors, stacking transistors, or the like) in lieu of or in combination with the nanostructure-FETs.

According to various embodiments, dummy gate regions are used to form lower power nanostructure-FETs and higher power nanostructure-FETs on the same substrate. In embodiments in which dummy regions (e.g., disposable oxide interposers or the like) are formed between nanostructures, some dummy regions are not removed for lower power nanostructure-FETs, forming dummy gate regions on some nanostructures of the lower power nanostructure-FETs. Forming dummy gate regions allows both lower power and higher power nanostructure-FETs to be formed. For example, the dummy gate regions are formed in wafer regions of lower power nanostructure-FETs and are not formed in wafer regions of higher power nanostructure-FETs.

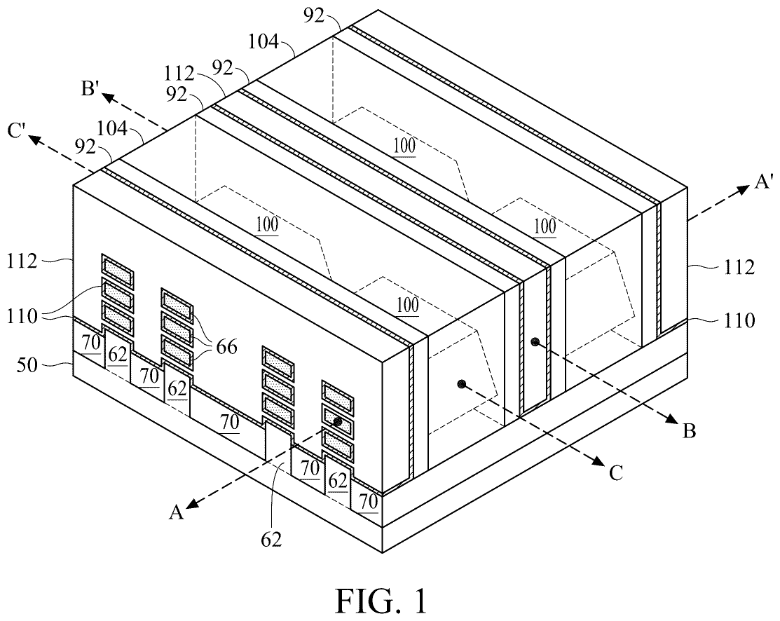

FIG. 1 illustrates an example of nanostructure-FETs (e.g., nanowire FETs, nanosheet FETs, nano-FETs, or the like), gate-all-around (GAA) FETs, or the like) in a three-dimensional view, in accordance with some embodiments. Some features of the nanostructure-FETs may be simplified and/or omitted in FIG. 1 for clarity. The nanostructure-FETs comprise nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. The nanostructures 66 may include p-type nanostructures, n-type nanostructures, or a combination thereof. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Some portions of the isolation regions 70 may be covered by a protective layer (not illustrated in FIG. 1). Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portions of the fins 62 and/or the substrate 50 may comprise a single material or a plurality of materials. In this context, the fins 62 refer to the portion extending between the neighboring isolation regions 70.

The gate dielectric layers 110 are over top surfaces of the fins 62 and along top surfaces, sidewalls, and bottom surfaces of the nanostructures 66. Gate electrodes 112 are over the gate dielectric layers 110. The gate dielectric layers 110 and gate electrodes 112 may be collectively be called “gate structures” or “gate stacks. ” Dummy gate regions (not illustrated in FIG. 1 and described in greater detail below) may be formed on bottom surfaces of some bottom-most nanostructures 66 and on top surfaces of some fins 62. Source/drain regions 100 are disposed on the fins 62 at opposing sides of the gate dielectric layers 110 and the gate electrodes 112. Source/drain region(s) 100 may refer to a source or a drain, individually or collectively dependent upon the context. An inter-layer dielectric (ILD) 104 is formed over the source/drain regions 100. Contacts (subsequently described) to the source/drain regions 100 will be formed through the ILD 104. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

FIG. 1 further illustrates reference cross-sections that are used in later figures. Cross-section A-A′ is along a longitudinal axis of a fin 62 of a nanostructure-FET and in a direction of, for example, a current flow between the source/drain regions 100 of the nanostructure-FET. Cross-section B-B′ is perpendicular to cross-section A-A′ and extends along a longitudinal axis of a gate electrode 112. Cross-section C-C′ is parallel to cross-section B-B′ (e.g., is perpendicular to cross-section A-A′) and extends through source/drain regions 100 of the nanostructure-FETs. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

Other FETs or configurations of FETs are possible.

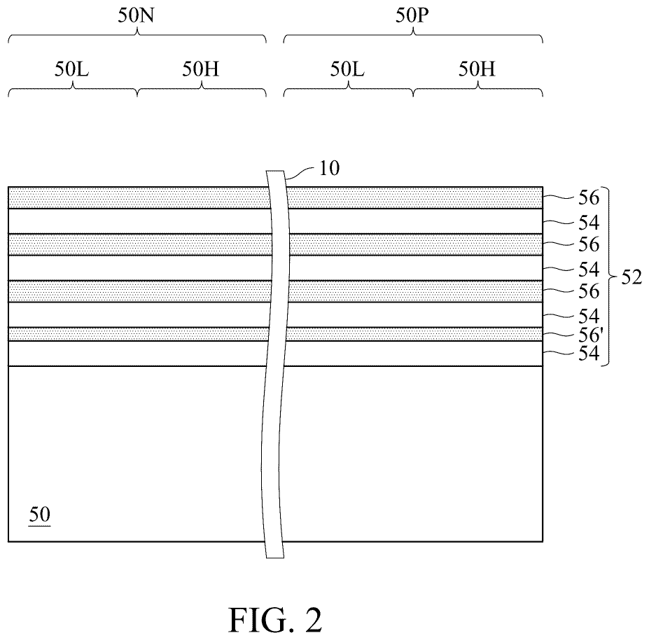

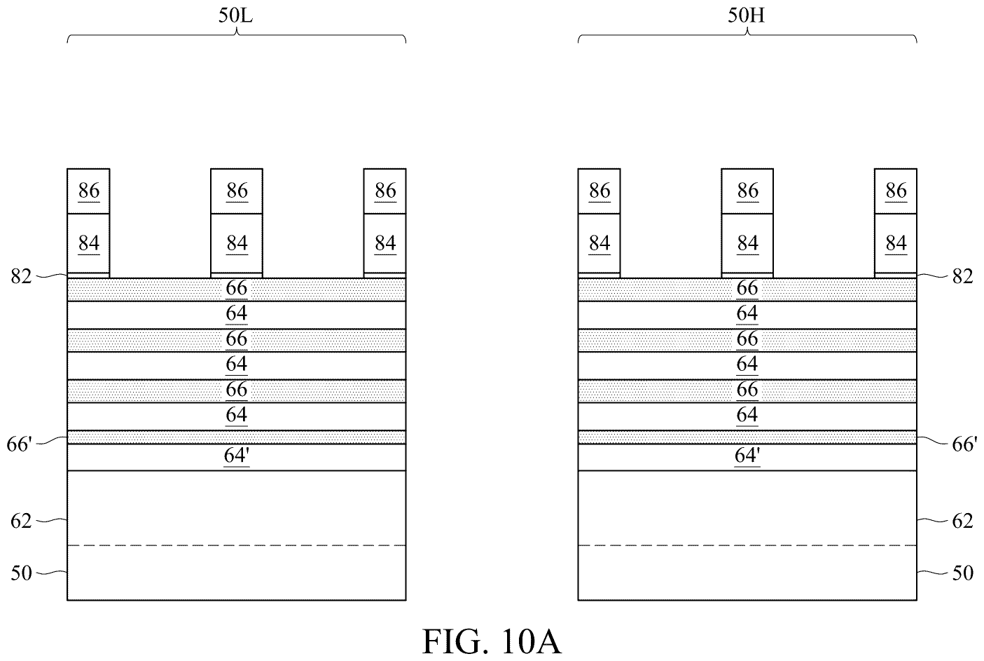

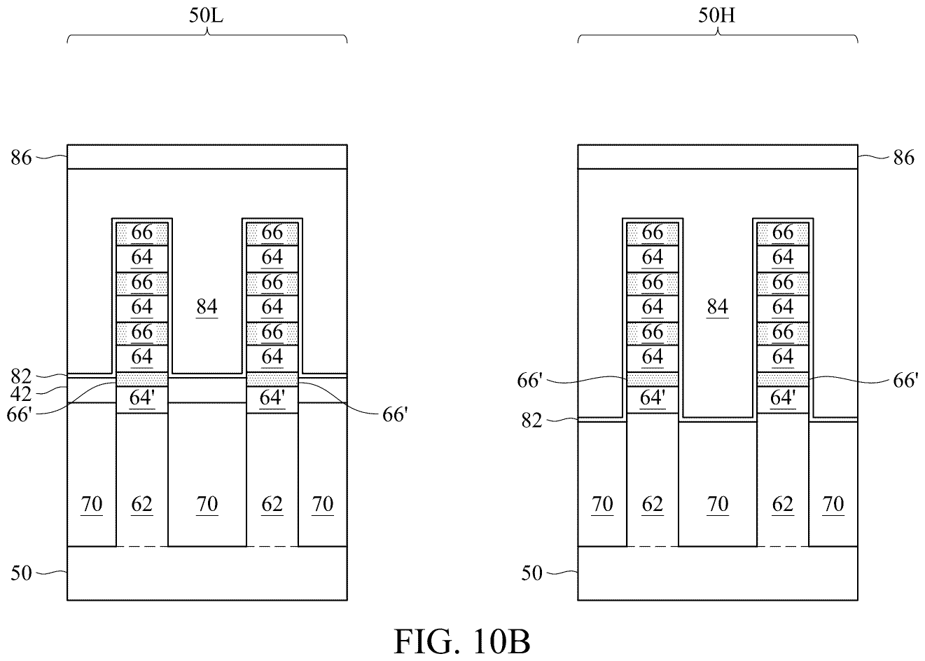

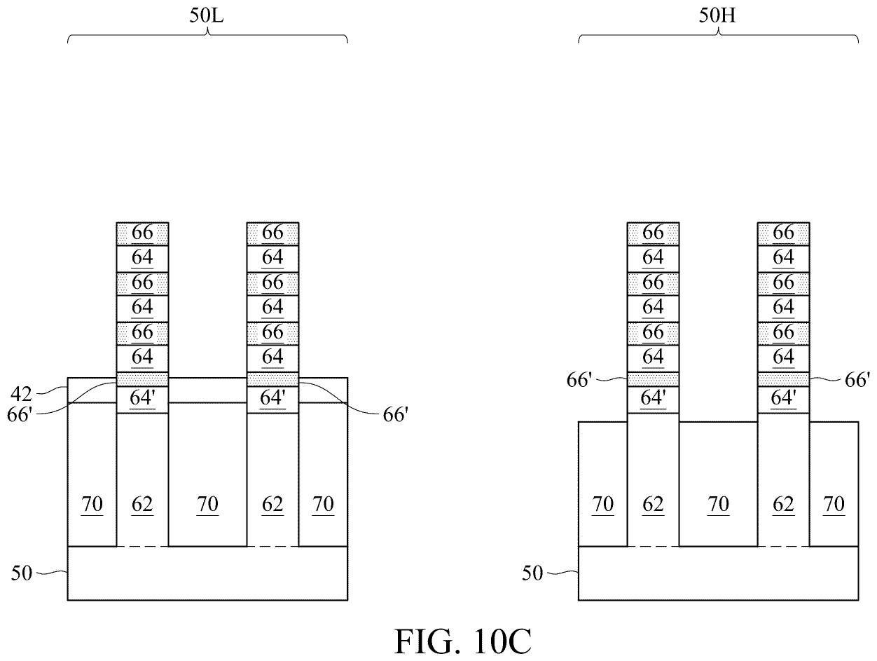

FIGS. 2-26C are views of intermediate stages in the manufacturing of nanostructure-FETs, in accordance with some embodiments. FIGS. 10A, 11A, 12A, 13A, 14A, 15A, 16A, 17A, 17B, 18A, 19A, 20A, 21A, 22A, 23A, 24, 25A, and 26A illustrate cross-sectional views along a similar cross-section as reference cross-section A-A′ in FIG. 1.

FIGS. 2, 3, 4, 5, 6, 7, 8, 9A, 9B, 10B, 11B, 12B, 13B, 14B, 15B, 16B, 18B, 19B, 20B, 21B, 22B, 23B, 25B, and 26B illustrate cross-sectional views along a similar cross-section as reference cross-section B-B′ in FIG. 1. FIGS. 10C, 11C, 12C, 18C, 18D, 25C, and 26C illustrate cross-sectional views along a similar cross-section as reference cross-section C-C′ in FIG. 1.

In FIG. 2, a substrate 50 is provided, in accordance with some embodiments. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer.

Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

The substrate 50 also has lower power regions 50L and higher power regions 50H. The lower power regions 50L can be for forming relatively lower power nanostructure-FETs, and the higher power regions 50H can be for forming relatively higher power nanostructure-FETs. As subsequently described in greater detail, the lower power nanostructure-FETs formed in the lower power regions 50L have smaller current performance than the higher power nanostructure-FETs formed in the higher power regions 50H. The techniques herein allow for the formation of both lower power nanostructure-FETs and higher power nanostructure FETs on the same substrate 50. The lower power regions 50L may (or may not) be physically separated (not separately illustrated) from the higher power regions 50H, and any number of device features (e.g., other active devices, doped regions, isolation structures, etc.) may be disposed between a lower power region 50L and a higher power region 50H. An n-type region 50N may have lower power regions 50L for n-type lower power nanostructure-FETs and higher power regions 50H for n-type higher power nanostructure FETs, and a p-type region 50P may have lower power regions 50L for p-type lower power nanostructure-FETs and higher power regions 50H for p-type higher power nanostructure FETs. Although one lower power region 50L and one higher power region 50H are illustrated in each of the n-type region 50N and the p-type region 50P, any number of lower power regions 50L and higher power regions 50H may be provided. A die or wafer having both lower power nanostructure-FETs and higher power nanostructure-FETs as described herein may be considered a “hybrid sheet structure” or a “hybrid nanostructure device”in some cases.

Further in FIG. 2, a multi-layer stack 52 is formed over the substrate 50, in accordance with some embodiments. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously.

The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one region (e.g., the p-type region 50P), and the second semiconductor layers 56 will be patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including four of the first semiconductor layers 54 and four of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52. For example, the bottom-most second semiconductor layer 56 (e.g., the second semiconductor layer 56 closest to the substrate 50) in FIG. 2 is thinner than overlying second semiconductor layers 56. Accordingly, the bottom-most second semiconductor layer 56 may be referred to as the bottom semiconductor layer 56′ to distinguish it from the other second semiconductor layers 56. In some cases, the bottom semiconductor layer 56′ may be relatively thin to improve short channel control in the resulting nanostructure-FETs. In some cases, a difference between a thickness of the bottom semiconductor layer 56′ and an overlying second semiconductor layer 56 may be about 1 nm or greater. Other combinations or variations of layer thicknesses are possible.

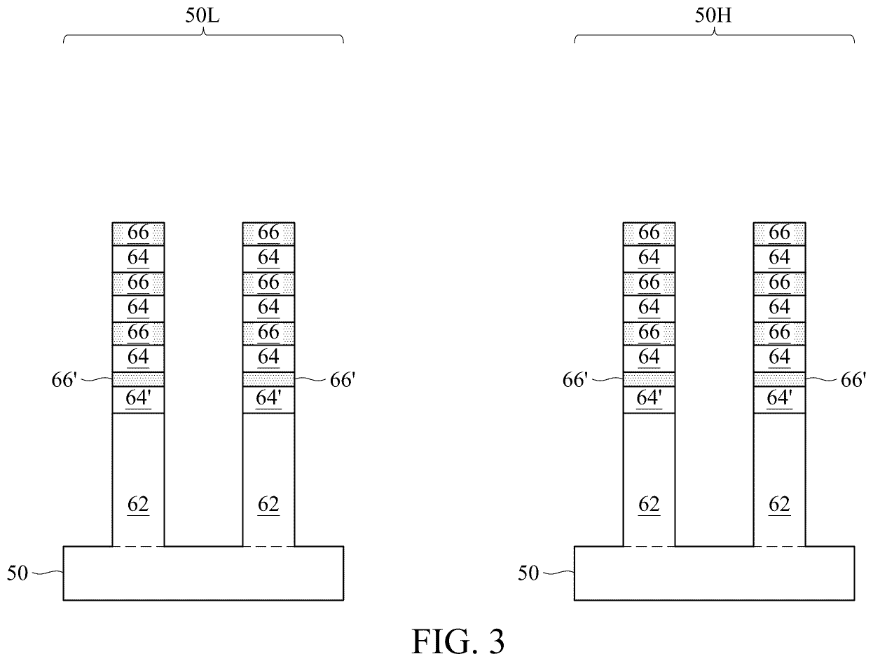

In FIG. 3, protrusions such as fins 62 are formed in the substrate 50, and first nanostructures 64 and second nanostructures 66 are formed in the multi-layer stack 52, in accordance with some embodiments.

The first nanostructures 64 and the second nanostructures 66 may be collectively referred to as the nanostructures 64/66 herein. FIG. 3 illustrates a lower power region 50L and a higher power region 50H of the substrate 50, which may be in either of the n-type region 50N or the p-type region 50P of the substrate 50 unless specifically discussed. The example fins 62 and nanostructures 64/66 shown in FIG. 3 for the lower power region 50L and the higher power region 50H may be the same fins 62 and nanostructures 64/66 (e.g., may be continuous structures extending between the lower power region 50L and the higher power region 50H), or the fins 62 and nanostructures 64/66 of the lower power region 50L may be separated from or adjacent to the fins 62 and nanostructures 64/66 of the higher power region 50H.

In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56. For example, the bottom semiconductor layer 56′ is patterned to form bottom-most second nanostructures 66, which may sometimes be referred to herein as second nanostructures 66′ or bottom nanostructures 66′ in the following description. Accordingly, the bottom nanostructures 66′ may be thinner than overlying second nanostructures 66, in some embodiments. The bottom-most first semiconductor layer 54 is patterned to form bottom-most first nanostructures 64, which may sometimes be referred to herein as first nanostructures 64′ or bottom nanostructures 64′ in the following description. Other combinations or variations of nanostructure thicknesses are possible.

The fins 62 and the nanostructures 64/66 may be patterned by any suitable method. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66.

The fins 62 are illustrated as having substantially equal widths in both the n-type region 50N and the p-type region 50P. In some embodiments, a width of the fins 62 in the n-type region 50N may be greater or less than a width of the fins 62 in the p-type region 50P. In some embodiments, a width of the fins 62 in a lower power region 50L may be greater or less than a width of the fins 62 in a higher power region 50H.

Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

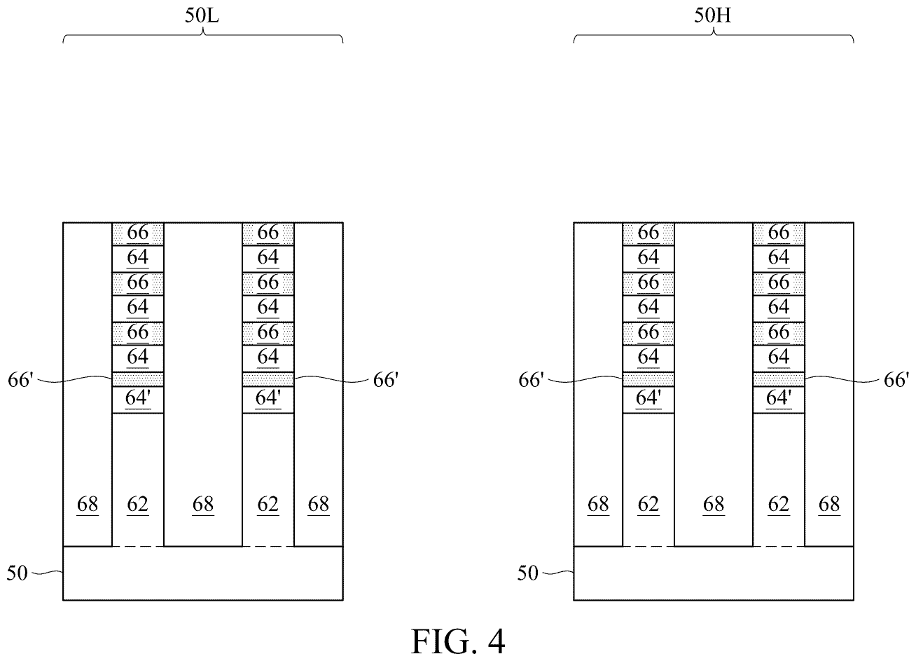

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, combinations thereof, or the like may be utilized. The planarization process exposes the nanostructures 64/66 such that top surfaces of the nanostructures 64/66 and the insulation material 68 are level after the planarization process is complete.

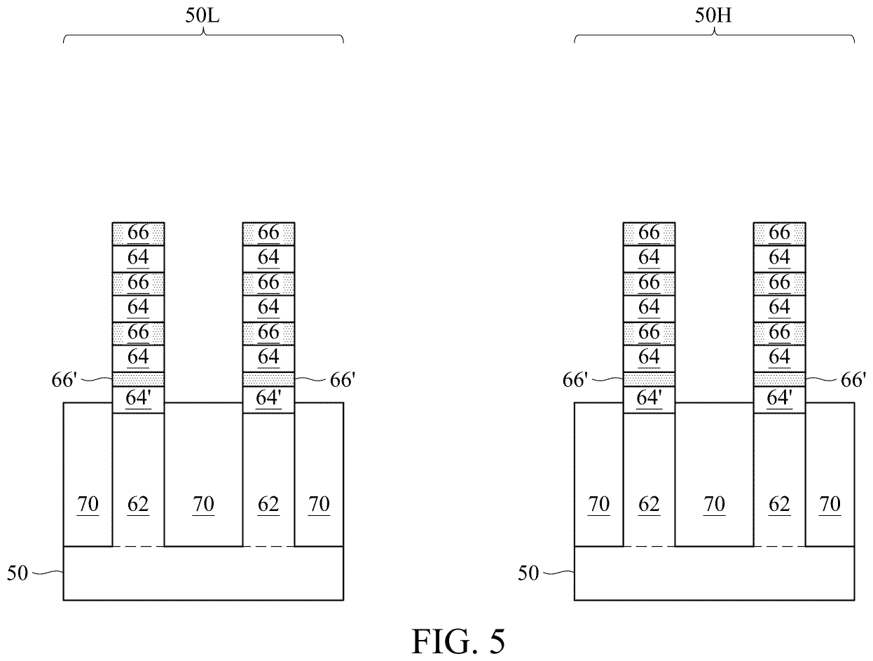

In FIG. 5, the insulation material 68 is recessed to form STI regions 70. The STI regions 70 are adjacent the fins 62. The insulation material 68 is recessed such that upper portions of fins 62 and/or the nanostructures 64/66 protrude from between neighboring STI regions 70.

The upper portions of the fins 62 and/or the nanostructures 64/66 are above the STI regions 70. In some cases, portions of the fins 62 and/or the nanostructures 64/66 may be below a top surface of the STI regions 70.

Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric (dHF) acid may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further in FIG. 5, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P.

The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

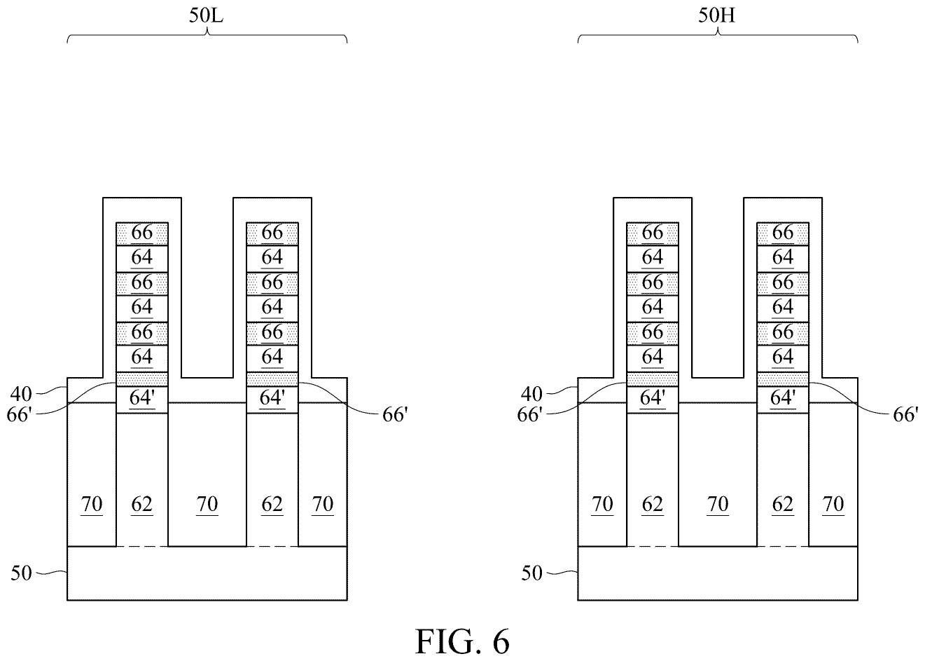

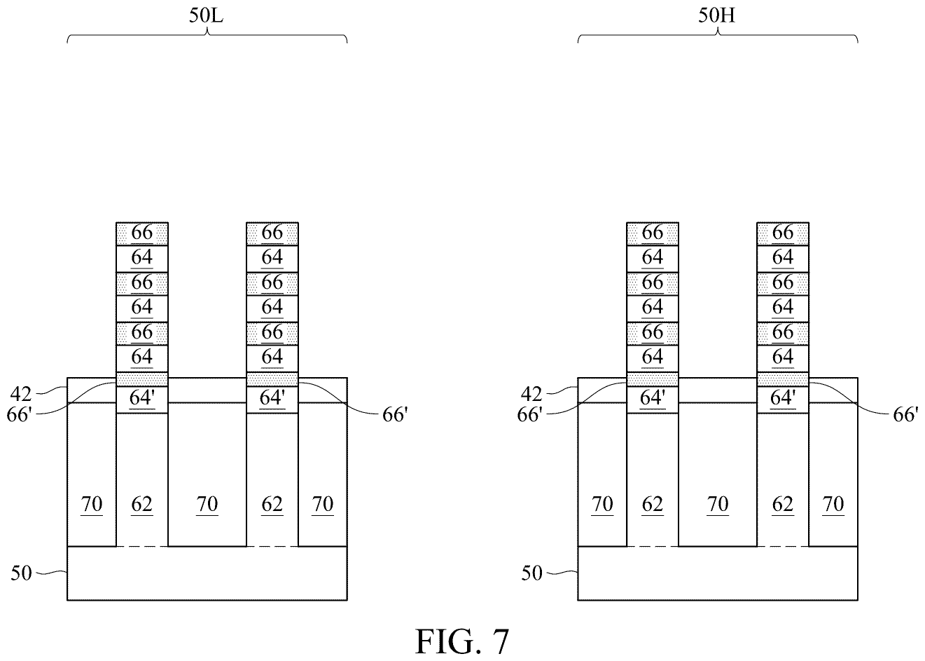

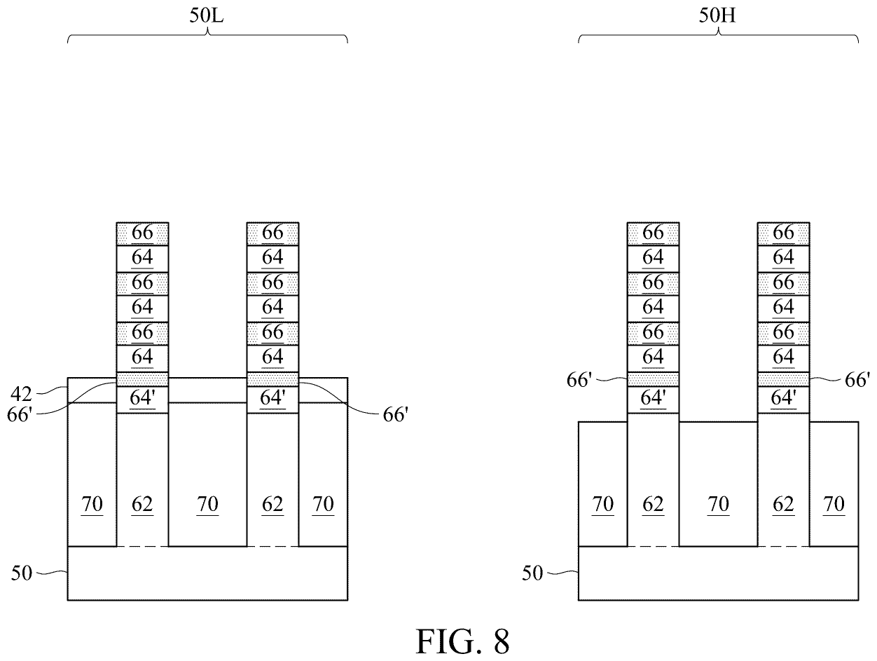

In FIG. 6, a protective material 40 is deposited over the STI regions 70, in accordance with some embodiments. The protective material 40 subsequently forms a protective layer 42 (see FIGS. 7-8) that may be formed on some top surfaces of the STI regions 70. The protective material 40 is deposited over top surfaces of the STI regions 70 and may be deposited on top surfaces of the nanostructures 64/66. The protective material 40 may also be deposited over and along sidewalls of the fins 62 and/or the nanostructures 64/66. Accordingly, the protective material 40 may be deposited as a continuous layer, in some cases. The protective material 40 may comprise one or more materials that have a high etching selectivity from the etching of the materials of the STI regions 70 and/or the nanostructures 64/66. In some embodiments, the protective material 40 may comprise a nitride, such as silicon nitride, silicon oxynitride, a silicon oxycarbonitride, or the like. In some embodiments, the protective material 40 comprises an oxide, such as hafnium oxide, zirconium oxide, or the like. Other materials are possible, and the protective material 40 may comprise multiple layers of different materials, in some cases. The protective material 40 may be deposited using a suitable process, such as CVD, plasma-enhanced CVD (PECVD), ALD, or the like. The deposition process may be conformal. In some cases, portions of the protective material 40 deposited on sidewall surfaces may be thinner than portions of the protective material 40 deposited on lateral surfaces (e.g., top surfaces).

In FIG. 7, the upper portions of the protective material 40 are removed to form the protective layer 42, in accordance with some embodiments. The upper portions of the protective material 40 may include portions on sidewalls of the fins 62 and/or sidewalls of the nanostructure 64/66 and may include portions on top surfaces of the nanostructures 64/66. As shown in FIG. 7, the remaining portions of the protective material 40 on top surfaces of the STI regions 70 form the protective layer 42. The upper portions of the protective material 40 may be removed using one or more acceptable etch processes, such as a dry etch, a wet etch, or a combination thereof. The etch process may be anisotropic. In some cases, the etch process may thin lateral portions of the protective material 40 that form the protective layer 42. In some cases, the protective layer 42 may be considered a hard mask (e.g., a “STI hard mask”) or the like.

The protective layer 42 may cover some sidewall surfaces of the fins 62 and/or the nanostructures 64/66, as shown in FIG. 7. In some cases, the protective layer 42 may fully cover a sidewall of a bottom nanostructure 64′. In some cases, a top surface of the protective layer 42 may be higher (e.g., farther from the substrate 50) than a top surface of a bottom nanostructure 64′. In some cases, a top surface of the protective layer 42 may be higher than a bottom surface of a bottom nanostructure 66′ and/or may be lower (e.g., closer to the substrate 50) than a top surface of a bottom nanostructure 66′. Accordingly, the protective layer 42 may partially or fully cover a sidewall of a bottom nanostructure 66′, in some embodiments. Further, the top surfaces of the protective layer 42 may have a flat surface as illustrated, a convex surface, a concave surface (such as dishing), or a combination thereof.

In FIG. 8, the remaining portions of the protective layer 42 in the higher power region 50H is removed, in accordance with some embodiments. Removing protective layer 42 in the higher power region 50H may include depositing a mask layer (not illustrated) over the lower power region 50L and the higher power region 50H. In some embodiments, the mask is a backside anti-reflective coating (BARC) layer that is deposited by PVD or the like. Other materials and/or deposition processes are possible in other embodiments. For example, in some embodiments, the mask is a photoresist or the like, which may be formed using a spin-on technique. The mask layer is patterned to expose the higher power region 50H. The mask layer can be patterned using acceptable photolithography and etching techniques. The protective layer 42 in the higher power region 50H may be removed using techniques similar to those described above for removing upper portions of the protective material 40. For example, an anisotropic dry etch may be used, in some embodiments.

In some embodiments, the STI regions 70 in the higher power region 50H may also be etched when removing the protective layer 42. The etching may recess portions of the STI regions 70 between the fins 62. In some embodiments, in the higher power region 50H, the STI regions 70 may be recessed such that a top surface of the STI regions 70 is lower (e.g., closer to the substrate 50) than a bottom surface of a bottom nanostructure 64′, as shown in FIG. 8. In this manner, recessing the STI regions 70 in the higher power region 50H may fully expose sidewalls of bottom nanostructures 64′, as shown in FIG. 8. The STI regions 70 may be recessed a smaller depth than shown or a greater depth than shown. In other embodiments, a top surface of the recessed STI regions 70 in the higher power region 50H may be about level with a bottom surface of a bottom nanostructure 64′ or may be higher than a bottom surface of a bottom nanostructure 64′. A top surface of the recessed STI regions 70 in the higher power region 50H may be higher than a top surface of a fin 62, about level with a top surface of a fin 62, or below a top surface of a fin 62. Although top surfaces of the recessed STI regions 70 are illustrated as being flat, the top surfaces may be concave or convex.

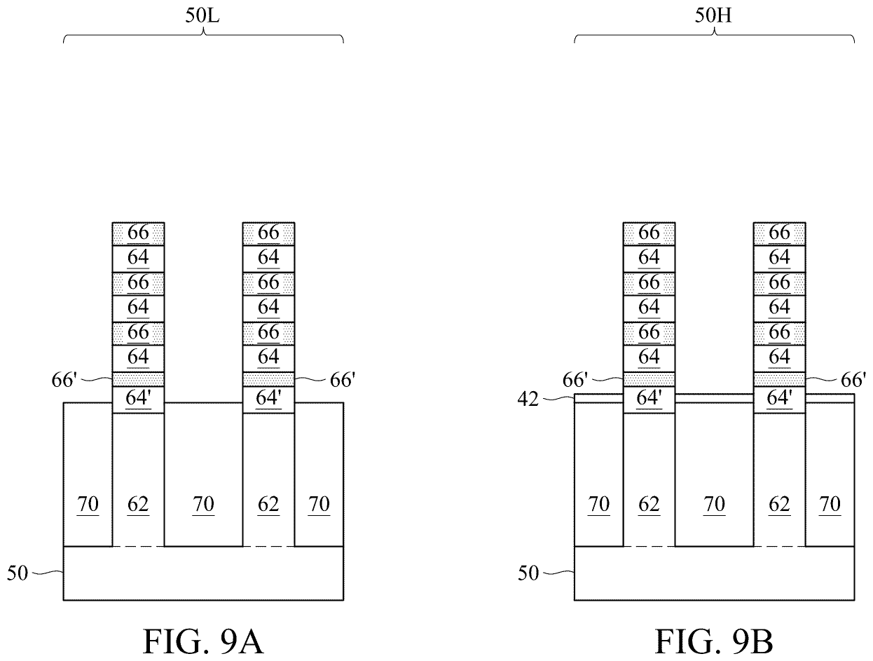

In other embodiments, the STI regions 70 in the higher power region 50H are not significantly etched when removing the protective layer 42. An example is shown in FIG. 9A, which is similar to the higher power region 50H shown in FIG. 8 except that the STI regions 70 are not recessed when the protective layer 42 is removed. In such embodiments, removing the protective layer 42 in the higher power region 50H exposes at least a portion of a sidewall of a bottom nanostructure 64′.

In other embodiments, the protective layer 42 in the higher power region 50H is thinned but not completely removed. An example is shown in FIG. 9B, which is similar to the higher power region 50H shown in FIG. 7 except that the protective layer 42 is thinned but remains covering the STI regions 70. In such embodiments, thinning the protective layer 42 in the higher power region 50H exposes at least a portion of a sidewall of a bottom nanostructure 64′. Accordingly, a top surface of the thinned protective layer 42 may be lower than a top surface of a bottom nanostructure 64′.

FIGS. 10A-10C are subsequent to the structure shown in FIG. 8, in which STI regions 70 in the higher power region 50H are recessed. FIG. 10A illustrates a cross-sectional view along a similar cross-section as reference cross-section A-A′ in FIG. 1. FIG. 10B illustrates a cross-sectional view along a similar cross-section as reference cross-section B-B′ in FIG. 1. FIG. 10C illustrates a cross-sectional view along a similar cross-section as reference cross-section C-C′ in FIG. 1.

In FIGS. 10A-10C, dummy dielectrics 82, dummy gates 84, and masks 86 are formed over and along sidewalls of the fins and/or the nanostructures 64/66, in accordance with some embodiments. In some embodiments, a dummy dielectric layer is formed on the fins 62 and/or the nanostructures 64/66. The dummy dielectric layer may be formed of silicon oxide, silicon nitride, a combination thereof, or the like, which may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP process or the like. The dummy gate layer may be formed of a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The material of the dummy gate layer may be deposited by CVD, physical vapor deposition (PVD), sputter deposition, or another suitable technique. The dummy gate layer may be formed of other materials that have a high etching selectivity from the etching of insulation materials, e.g., the STI regions 70 and/or the dummy dielectric layer. The mask layer may be deposited over the dummy gate layer. The mask layer may be formed of a dielectric material such as silicon nitride, silicon oxynitride, or the like.

Subsequently, the mask layer is patterned using acceptable photolithography and etching techniques to form masks 86. The pattern of the masks 86 then may be transferred to the dummy gate layer and to the dummy dielectric layer to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In this example, a single dummy gate layer and a single mask layer are formed across the n-type region 50N and the p-type region 50P. In the illustrated embodiment, the dummy dielectric layer covers protective layer 42 in the lower power region 50L and covers the STI regions 70 in the higher power region 50H, such that the dummy dielectrics 82 extends between the dummy gates 84 and the protective layer 42 in the lower power region 50L and extends between the dummy gates 84 and the STI regions 70 in the higher power region 50H. In another embodiment, the dummy dielectrics 82 covers only the fins 62 and/or the nanostructures 64/66.

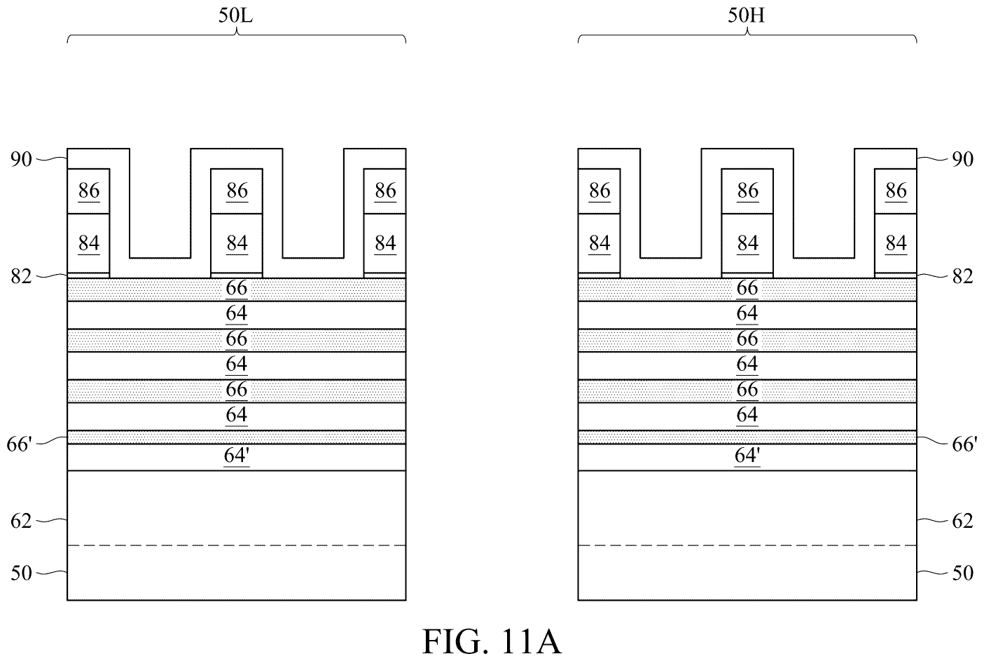

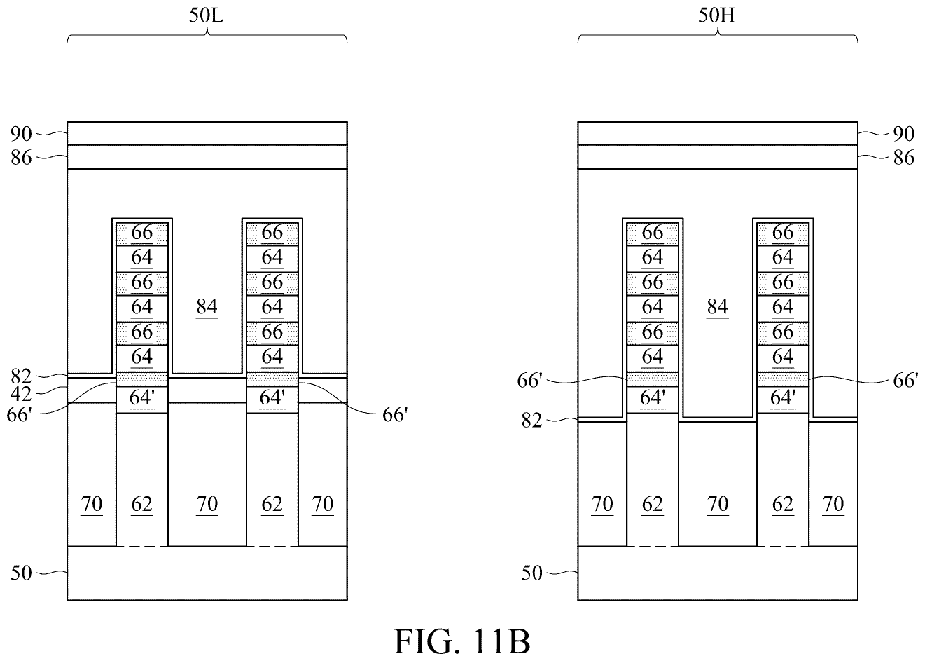

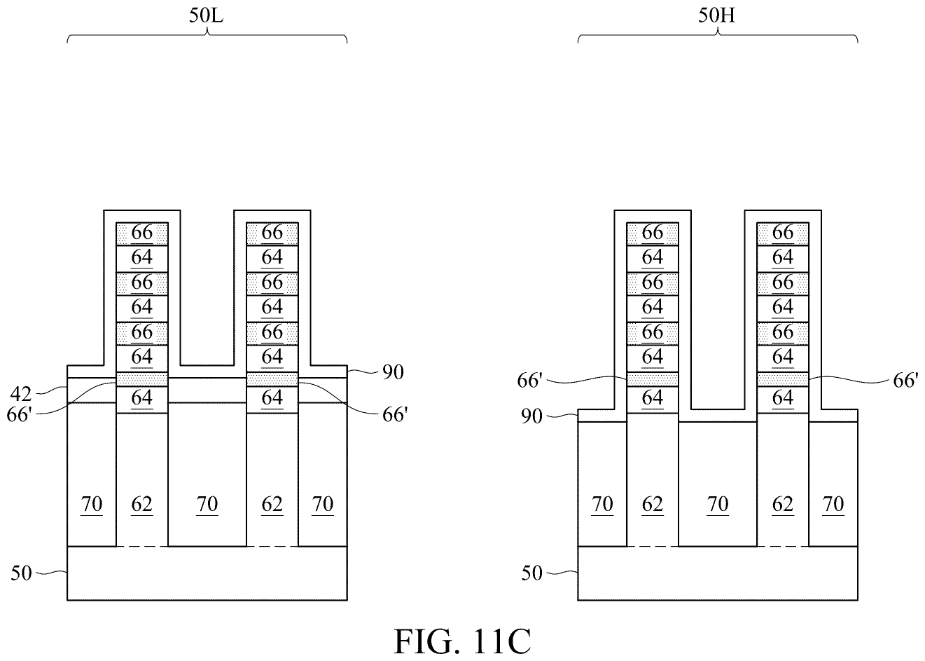

In FIGS. 11A-11C, a spacer layer 90 is conformally formed over the structure, in accordance with some embodiments. The spacer layer 90 is formed over the nanostructures 64/66, the protective layer 42, and the STI regions 70. The spacer layer 90 is also formed on exposed sidewalls of the masks 86 (if present), the dummy gates 84, the dummy dielectrics 82, the nanostructures 64/66, and/or the fins 62. The spacer layer 90 may be formed of one or more dielectric material(s). FIGS. 11A-11C show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 is subsequently etched to form spacers.

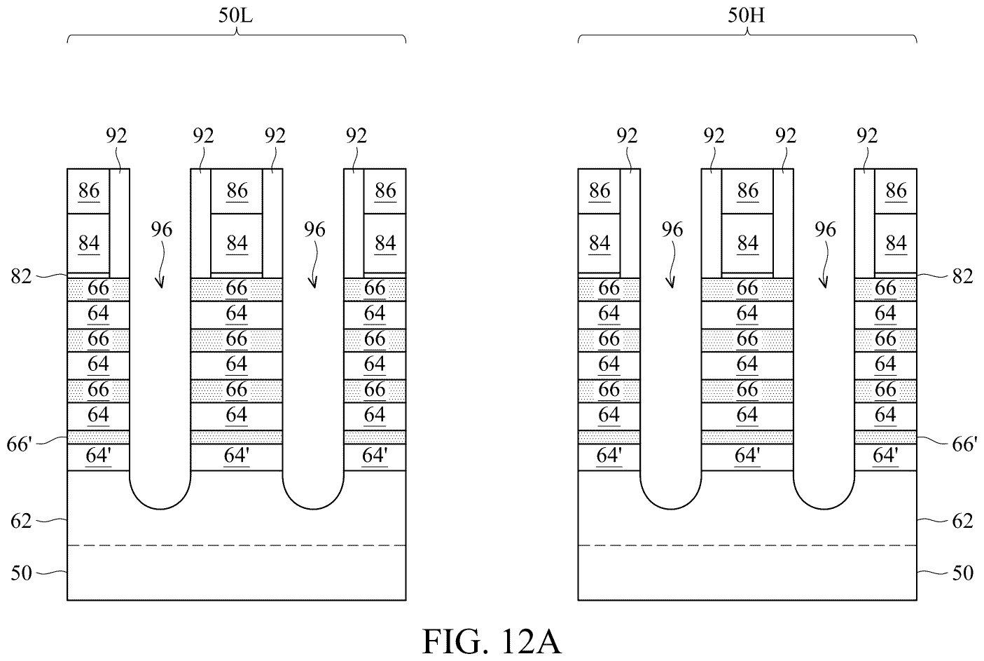

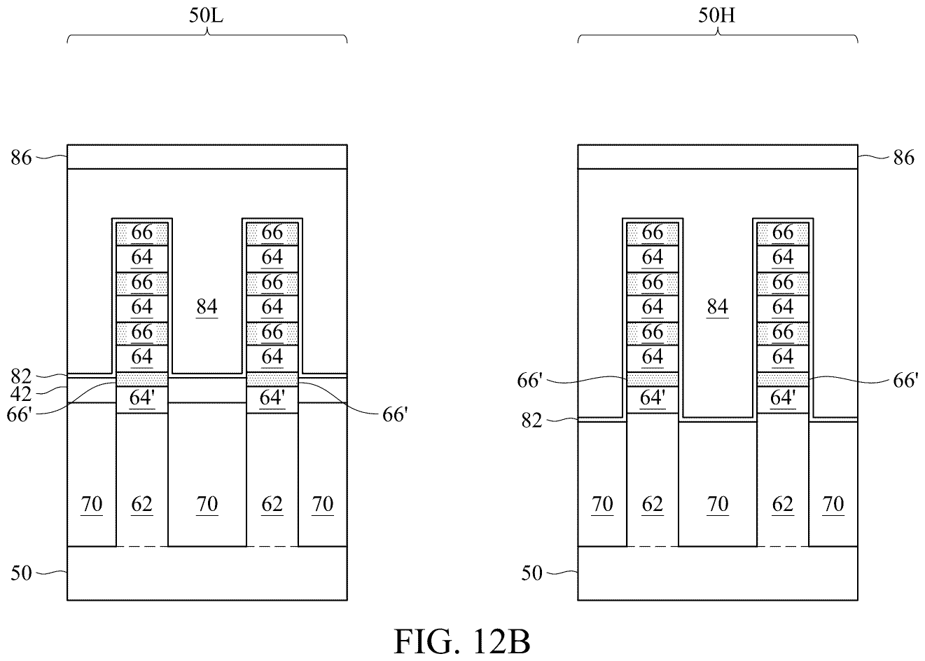

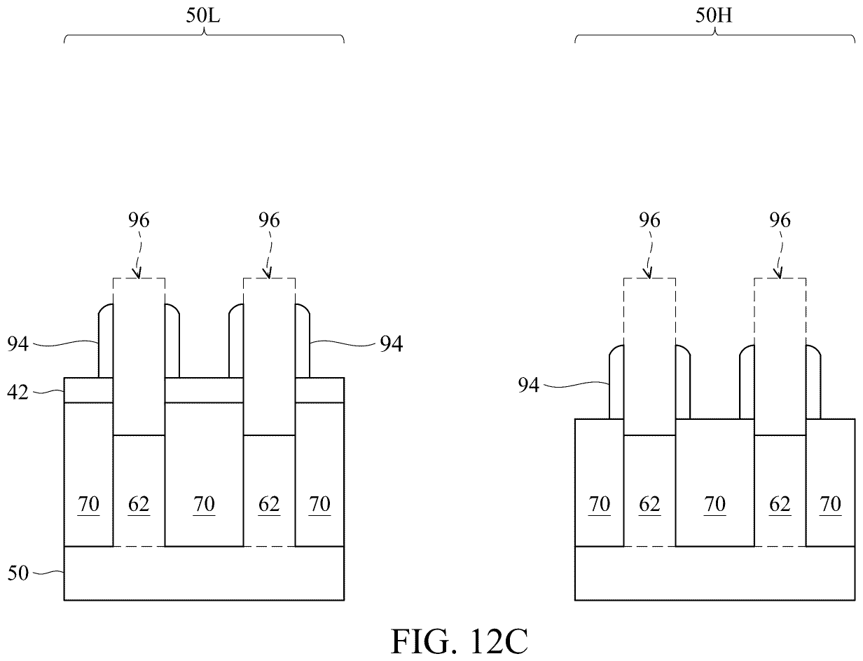

In FIGS. 12A-12C, the spacer layer 90 is patterned to form gate spacers 92 and fin spacers 94. Any acceptable etch process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 can have straight sidewalls or can have curved sidewalls. In some embodiments, the protective layer 42 and/or the STI regions 70 may also be etched when patterning the spacer layer 90. For example, the etching may recess portions of the protective layer 42 and/or the STI regions 70 between the fins 62. The gate spacers 92 and/or the fin spacers 94 can have straight sidewalls (as illustrated) or can have curved sidewalls (not separately illustrated).

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed.

Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 12A-12C, source/drain recesses 96 are patterned in the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are lower than the top surfaces of the STI regions 70, as shown in FIG. 12C. In other embodiments, the bottom surfaces of the source/drain recesses 96 are about level with or higher than top surfaces of the STI regions 70. The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, and the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth.

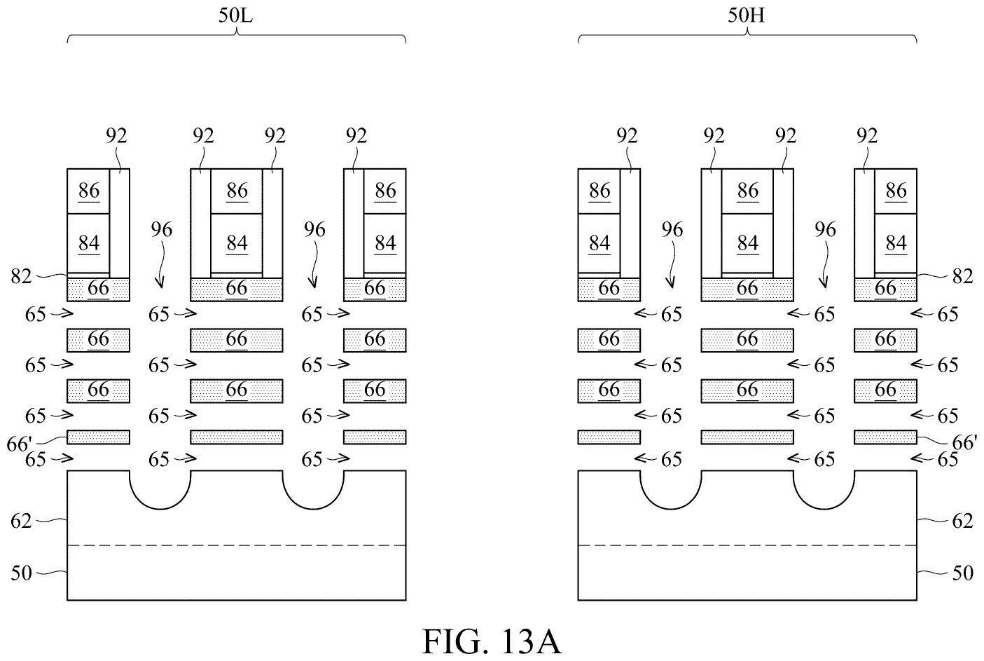

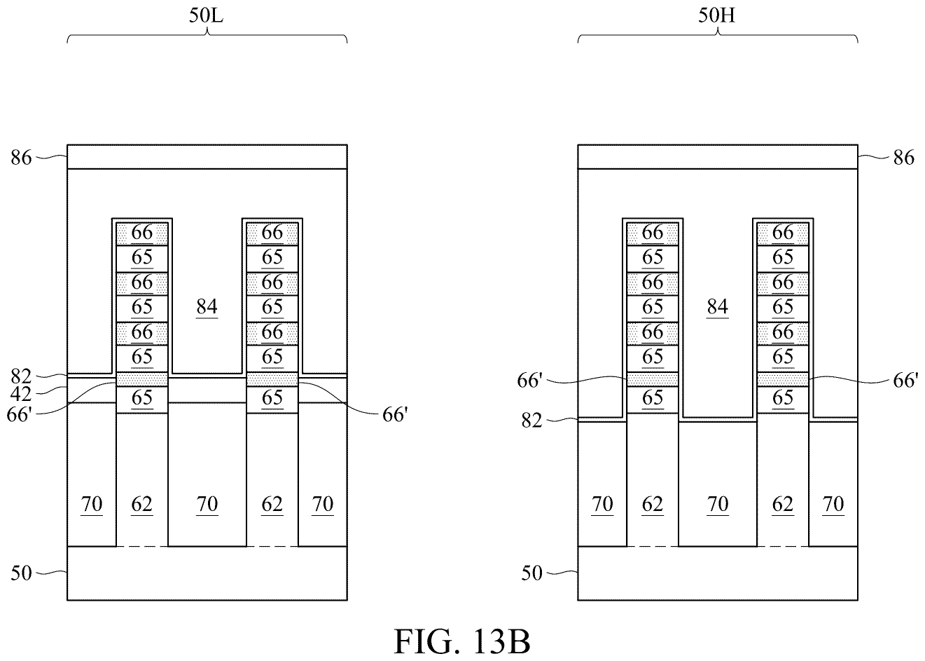

In FIGS. 13A-13B, the remaining portions of the first nanostructures 64 are then removed to form openings 65 in regions between the second nanostructures 66. The remaining portions of the first nanostructures 64 may be removed using an etch process that is performed through the source/drain recesses 96. The etch process may include any acceptable etch process that selectively etches the material of the first nanostructures 64 at a faster rate than the material of the second nanostructures 66 and the fins 62. The etch process may include a wet etch process and/or a dry etch process, and the etching may isotropic. For example, when the first nanostructures 64 are formed of e.g., silicon germanium and the second nanostructures 66 are formed of e.g., silicon or silicon carbide, the etch process may be a wet etch using tetramethylammonium hydroxide (TMAH), ammonium hydroxide (NH₄OH), or the like. In other embodiments, the etch process may be a dry etch using fluorine (F₂), ammonia (NH₃), hydrofluoric acid (HF), chlorine trifluoride (ClF₃), XeF₃, or the like. In some embodiments, a trim process (not illustrated) is performed to decrease the thicknesses of the exposed portions of the second nanostructures 66 and expand the openings 65. Hereinafter, the second nanostructures 66 may be referred to as nanostructures 66, and the collections of vertically adjacent nanostructures 66 over each fin 62 may be referred to as “stacks”of nanostructures 66.

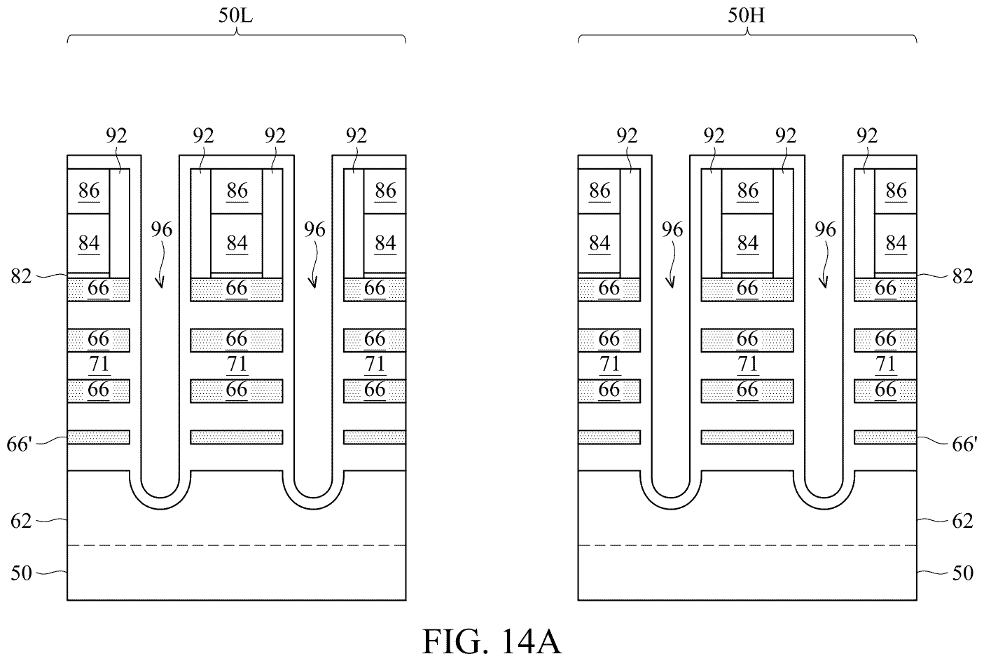

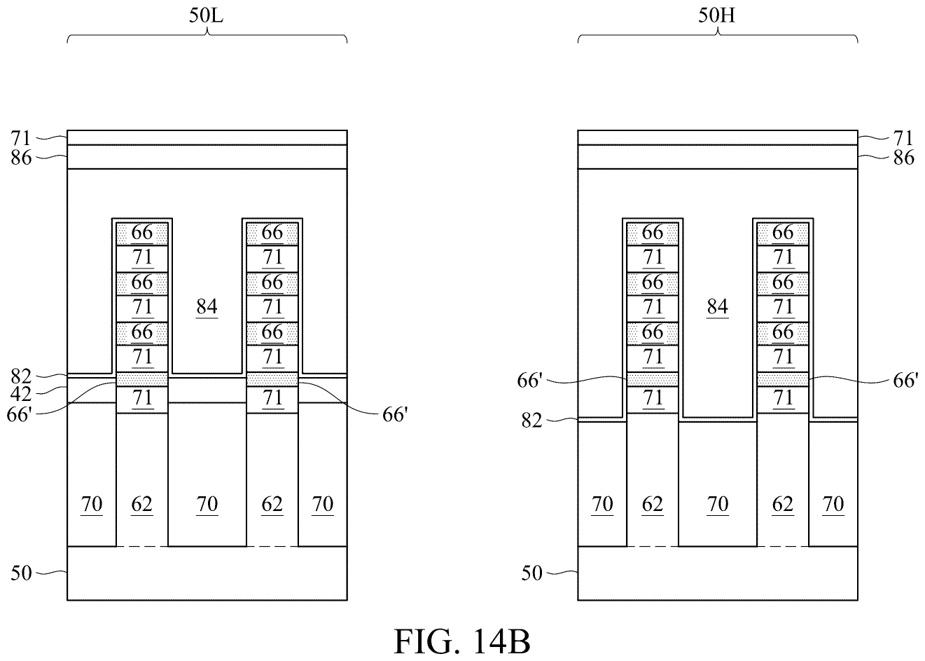

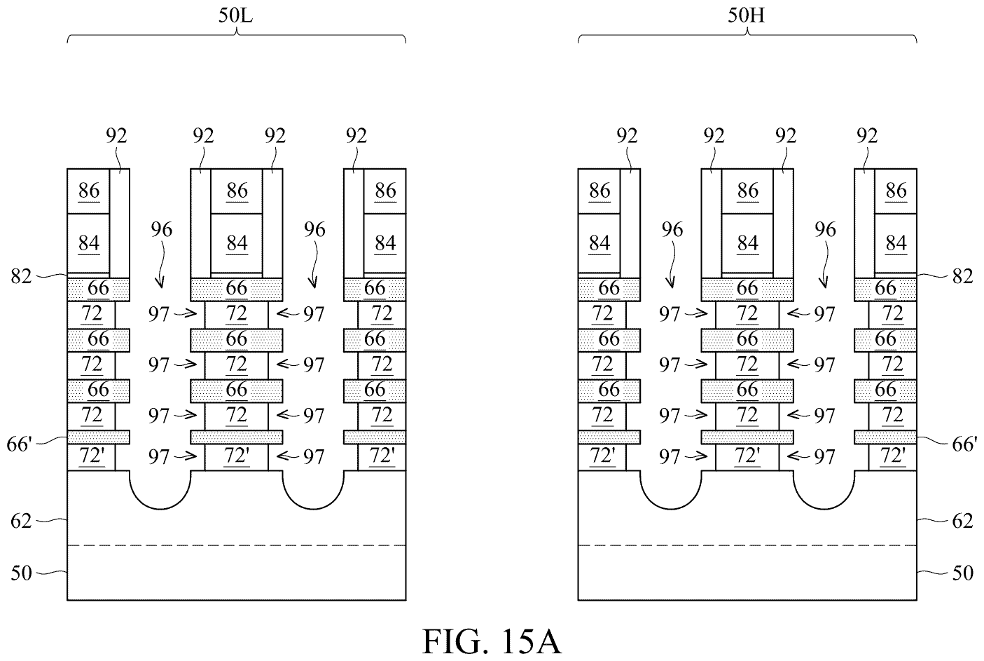

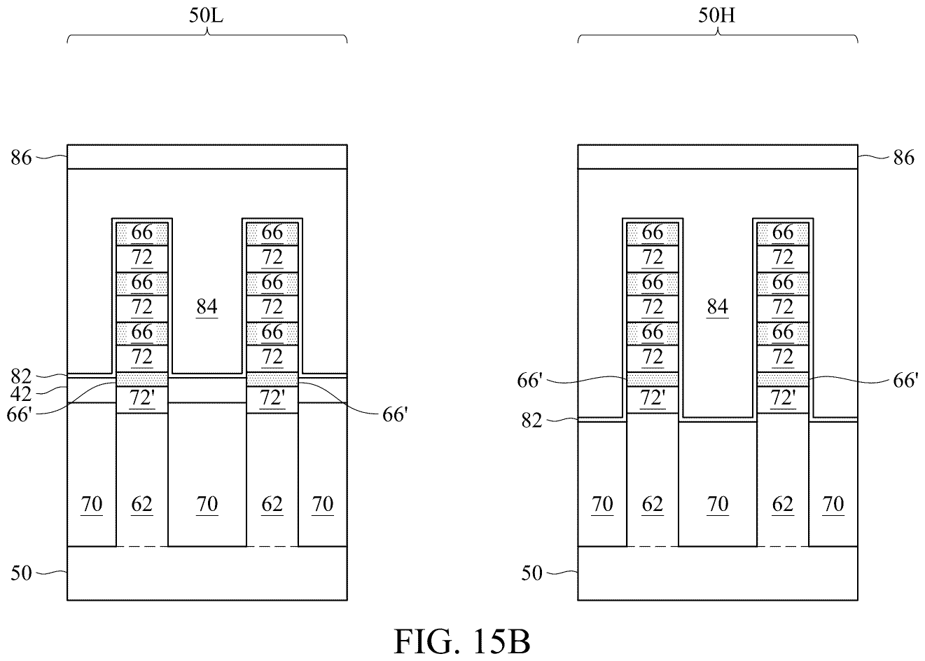

In FIGS. 14A-15B, the first nanostructures 64 are replaced with a dummy material 71 to form dummy regions 72, in accordance with some embodiments. In some cases, the dummy material 71 may be considered a sacrificial material or a sacrificial oxide. In some cases, the dummy regions 72 may be considered sacrificial regions, dummy oxide regions, dummy nanostructures, or disposable oxide interposers (DOI).

Replacing the first nanostructures 64 with dummy regions 72 may provide advantages. For example, in subsequent source/drain formation steps, one or more high temperature processes may be performed to, for example, activate the dopants in the source/drain regions. When the material of the first nanostructures 64 (e.g., silicon germanium or the like) is exposed to high temperatures, germanium intermixing and increased roughness at interfaces between the nanostructures 64 and 66 may result. Such manufacturing defects may degrade the performance of the resulting transistor devices. For example, when germanium diffuses into the second nanostructures 66, germanium residue may remain in channel regions of the resulting transistor devices, which negatively affects the performance of the channel regions. By replacing the first nanostructures 64 with an insulating material (e.g., the dummy regions 72) prior to the high temperature processes (e.g., source/drain annealing), manufacturing defects can be reduced and device performance can be improved (e.g., increased current drive, reduced capacitance, and improved short channel effect).

In FIGS. 14A-14B, a dummy material 71 is deposited in the recesses 96 and in the openings 65, in accordance with some embodiments. The dummy material 71 may be deposited by a conformal deposition process, such as CVD, ALD, or the like. The dummy material 71 may comprise an insulating material such as silicon oxide or the like that can be selectively etched from the nanostructures 66 and the fins 62. As shown in FIGS. 14A-14B, the dummy material 71 may fill or overfill the openings 65 and may cover sidewalls of the nanostructures 66. For example, the dummy material 71 fills the openings 65 formed by the removal of the bottom nanostructures 64′. The dummy material 71 may cover top surfaces of the fins 62. In some embodiments, the dummy material 71 does not completely fill the source/drain recesses 96.

In FIGS. 15A-15B, the dummy material 71 may then be etched to form the dummy regions 72. The etching may be isotropic or anisotropic. For example, the dummy material 71 may be etched using a wet etch process, such as diluted HF or the like. In some embodiments, the etching is performed until sidewalls of the dummy material 71 are recessed past sidewalls of the nanostructures 66, forming sidewall recesses 97.

Accordingly, the dummy regions 72 may have a width that is smaller than a width of the nanostructures 66. In some cases, the sidewall recesses 97 may be considered part of the source/drain recesses 96. Although sidewalls of the dummy regions 72 within the sidewall recesses 97 are illustrated as being flat, the sidewalls may be concave or convex. The bottom-most dummy regions 72 (e.g., the dummy regions 72 that replace the bottom nanostructures 64′) may be referred to herein as bottom dummy regions 72′ or dummy gate regions 72′.

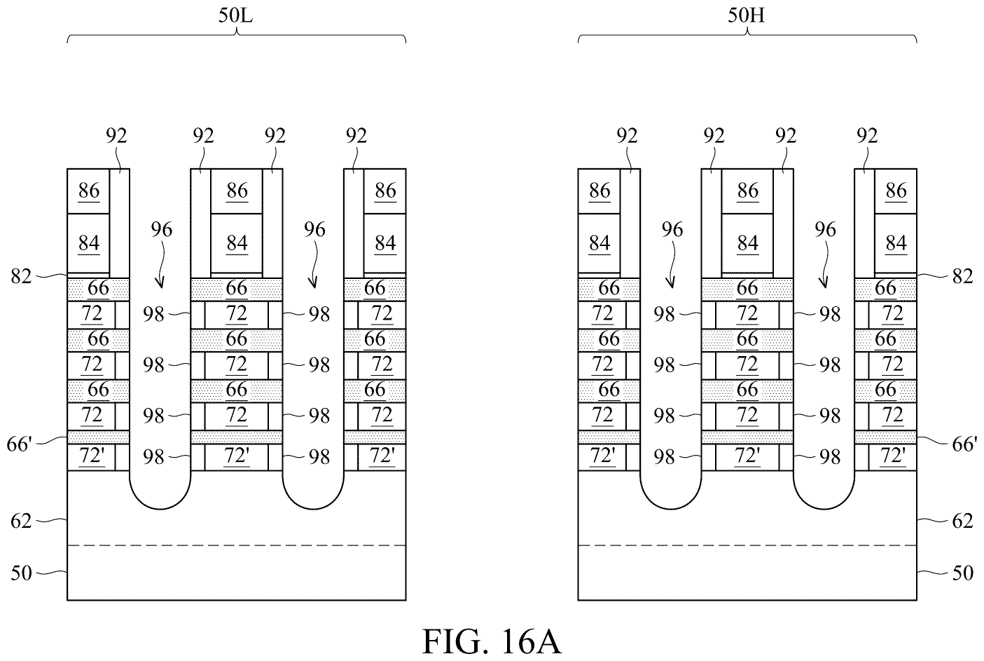

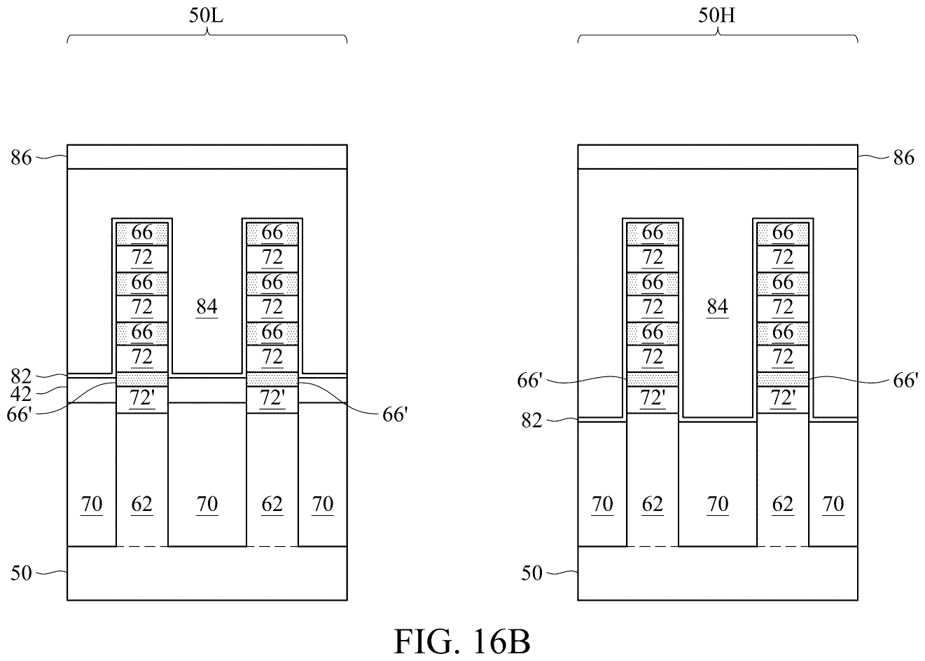

In FIGS. 16A-16B, inner spacers 98 are formed in the sidewall recesses 97, in accordance with some embodiments. In other words, the inner spacers 98 are formed on the sidewalls of the dummy regions 72. As will be subsequently described in greater detail, source/drain regions are subsequently formed in the source/drain recesses 96, and the first nanostructures 64 will be subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes. As shown in FIGS. 16A-16B, sidewalls of the bottom dummy regions 72′ in the lower power region 50L are fully covered by inner spacers 98 in the cross-sectional view of FIG. 16A, and sidewalls of the bottom dummy regions 72′ are fully covered by the protective layer 42 in the cross-sectional view of FIG. 16B. In this manner, the inner spacers 98 and the protective layer 42 collectively surround (e.g., encircle) respective bottom dummy regions 72′ in the lower power region 50L.

In some embodiments, the inner spacers 98 are formed by conformally depositing an insulating material in the source/drain recesses 96 and in the sidewall recesses 97 and subsequently etching the insulating material. The insulating material may be silicon nitride, silicon oxynitride, or the like. However, any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98. An inner spacer 98 may have a thickness that is smaller than, about the same as, or greater than a thickness of an adjacent dummy region 72.

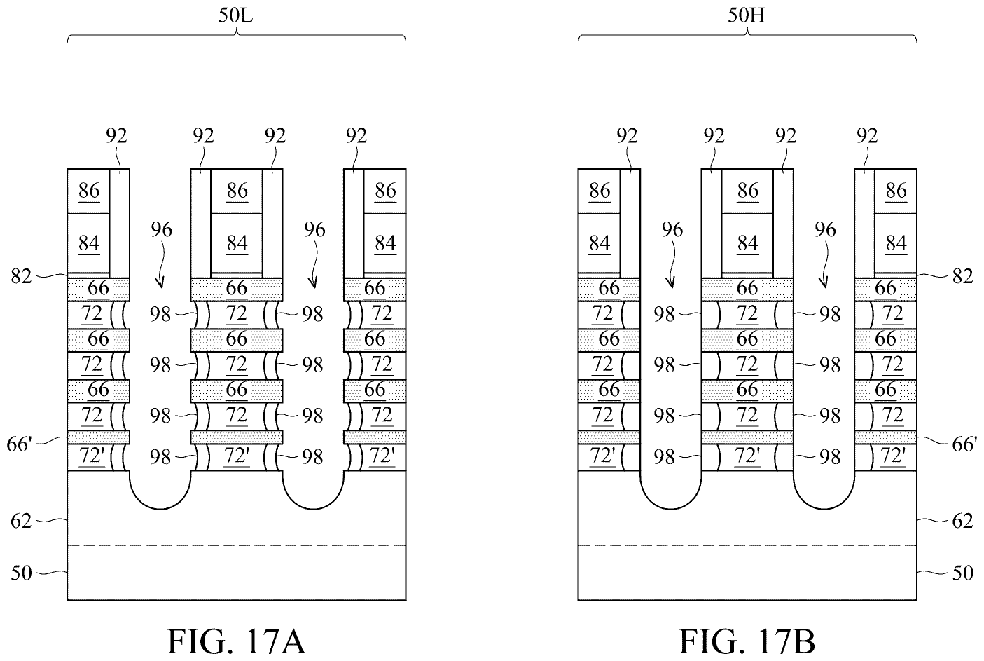

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat in FIG. 16A, the sidewalls of the inner spacers 98 may be concave or convex. As an example, FIG. 17A illustrates an embodiment in which sidewalls of the dummy regions 72 are concave, outer sidewalls of the inner spacers 98 are concave, and inner spacers 98 are recessed from sidewalls of the nanostructures 66. As another example, FIG. 17B illustrates an embodiment in which sidewalls of the dummy regions 72 are concave, outer sidewalls of the inner spacers 98 are flat, and inner spacers 98 are flush with sidewalls of the nanostructures 66. Other configurations are also possible.

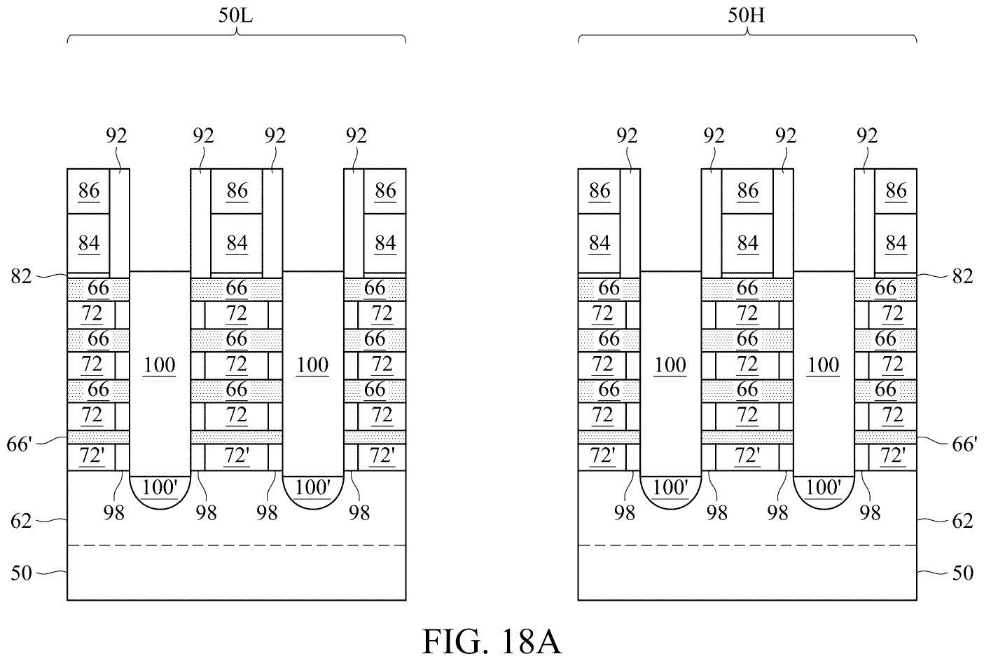

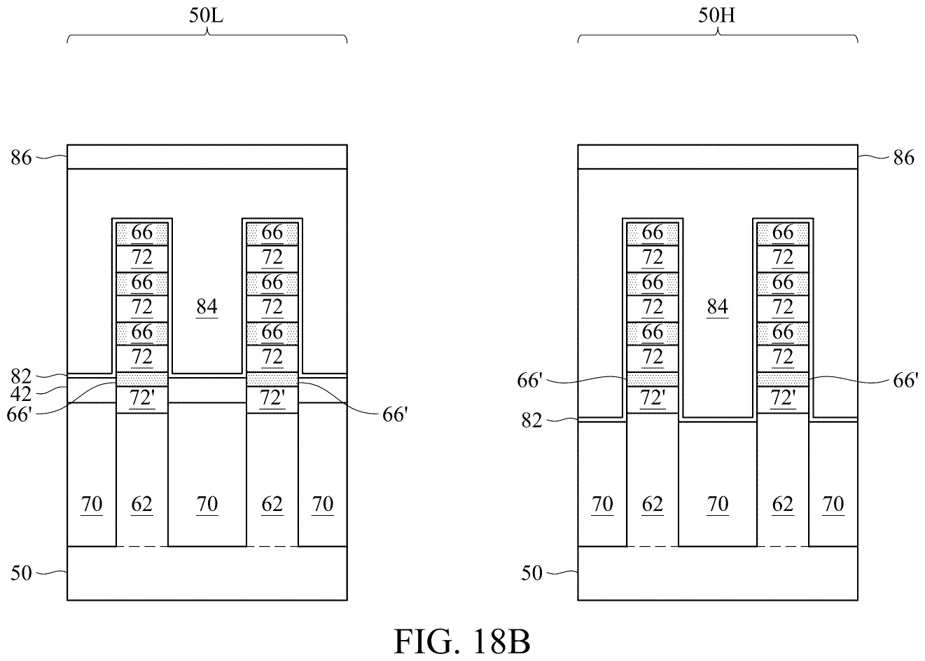

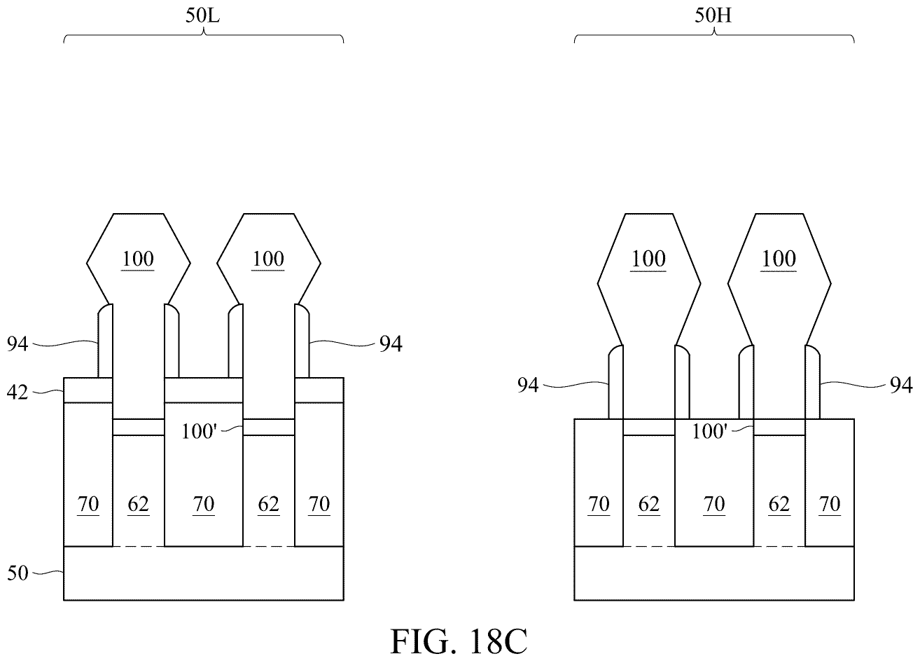

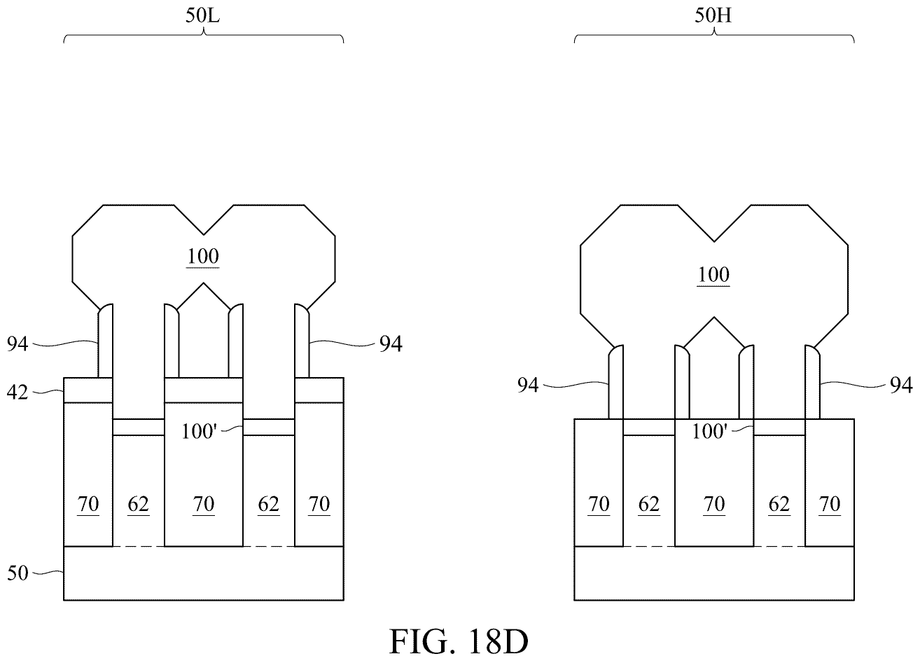

In FIGS. 18A-18C, epitaxial source/drain regions 100 are formed in the source/drain recesses 96 of the n-type region 50N and in the source/drain recesses 96 of the p-type region 50P, in accordance with some embodiments. The epitaxial source/drain regions 100 may also be referred to as “source/drain regions 100.” For example, the epitaxial source/drain regions 100 in the n-type region 50N may be referred to as “n-type source/drain regions,” and the epitaxial source/drain regions 100 in the p-type region 50P may be referred to as “p-type source/drain regions. ” The n-type source/drain regions 100 may be formed before, after, or simultaneously with the formation of the p-type source/drain regions 100.

The epitaxial source/drain regions 100 may be formed by an epitaxy process, such as such as vapor phase epitaxy (VPE), molecular beam epitaxy (MBE), or the like.

In some embodiments, a semiconductor layer 100′ may be formed in the source/drain recesses 96 before forming the epitaxial source/drain regions 100 in the source/drain recesses 96. The semiconductor layer 100′ may comprise, for example, undoped silicon or the like. Although the top surfaces of the semiconductor layer 100′ are illustrated as being flat (e.g., planar), the top surfaces of the semiconductor layers 100′ may be concave or convex. In other embodiments, an insulating layer (not illustrated) may be deposited in the source/drain recesses before forming the epitaxial source/drain regions 100 in the source/drain recesses 96. Top surfaces of the semiconductor layer 100′ may be higher than, approximately level with, or below top surfaces of the fins 62. In some embodiments, the semiconductor layer 100′ is not in physical contact with the inner spacers 98. In other embodiments, the semiconductor layer 100′ may be in physical contact with the sidewalls of some inner spacers 98. In other embodiments, the semiconductor layer 100′ may be formed prior to formation of the inner spacers 98, such that the inner spacer 98 material may cover the semiconductor layer 100′ In such embodiments, the epitaxial source/drain regions 100 may be formed on the inner spacer 98 material such that the inner spacer 98 material is between the epitaxial source/drain regions 100 and the semiconductor layer 100′. In other embodiments, a dielectric material may be deposited on the semiconductor layer 100′ in a separate deposition step such that the dielectric material is between the epitaxial source/drain regions 100 and the semiconductor layer 100′.

In some embodiments, the epitaxial source/drain regions 100 exert stress on channel regions of the nanostructures 66 within the n-type region 50N and/or within the p-type region 50P, thereby improving performance. The epitaxial source/drain regions 100 are formed in the source/drain recesses 96 such that each dummy gate 84 of the p-type region 50P is disposed between respective neighboring pairs of the epitaxial source/drain regions 100. In some embodiments, the gate spacers 92 are used to separate the epitaxial source/drain regions 100 from the dummy gates 84, and the inner spacers 98 are used to separate the epitaxial source/drain regions 100 from the nanostructures 64 by an appropriate flateral distance such that the epitaxial source/drain regions 100 do not short out with subsequently formed gates of the resulting nanostructure-FETs.

The epitaxial source/drain regions 100 in the n-type region 50N may be formed by masking the p-type region 50P. Then, n-type source/drain regions 100 are epitaxially grown in the source/drain recesses 96 in the n-type region 50N. The n-type source/drain regions 100 may include any acceptable material appropriate for n-type nanostructure-FETs. For example, if the nanostructures 66 are silicon, the n-type source/drain regions 100 may include materials exerting a tensile strain on the nanostructures 66, such as silicon, silicon carbide, phosphorous doped silicon carbide, silicon phosphide, or the like.

The epitaxial source/drain regions 100 in the p-type region 50P may be formed by masking the n-type region 50N. Then, p-type source/drain regions 100 are epitaxially grown in the source/drain recesses 96 in the p-type region 50P. The p-type source/drain regions 100 may include any acceptable material appropriate for p-type nanostructure-FETs. For example, if the nanostructures 66 are silicon, the p-type source/drain regions 100 may include materials exerting a compressive strain on the nanostructures 66, such as silicon-germanium, boron doped silicon-germanium, germanium, germanium tin, or the like.

The epitaxial source/drain regions 100, nanostructures 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 100 may be in situ doped during growth.

As a result of the epitaxy processes used to form the epitaxial source/drain regions 100 in the n-type region 50N and the p-type region 50P, upper surfaces of the epitaxial source/drain regions 100 have facets which expand laterally outward beyond sidewalls of the nanostructures 66. In some embodiments, adjacent epitaxial source/drain regions 100 remain separated after the epitaxy process is completed, as illustrated by FIG. 18C. In other embodiments, these facets cause adjacent epitaxial source/drain regions 100 of a same nanostructure-FET to merge, as illustrated by FIG. 18D. In the embodiments illustrated in FIGS. 18C and 18D, the fin spacers 94 may be formed on top surfaces of the protective layer 42 or the STI regions 70, thereby blocking the epitaxial growth. In some other embodiments, the fin spacers 94 may cover portions of the sidewalls of the nanostructures 66, further blocking the epitaxial growth. In some other embodiments, the spacer etch used to form the fin spacers 94 may be adjusted to remove the spacer material to allow the epitaxially grown region to extend to the surface of the protective layer 42 or the STI regions 70.

The n-type source/drain regions 100 and/or the p-type source/drain regions 100 may comprise one or more semiconductor material layers. Any number of semiconductor material layers may be used for the epitaxial source/drain regions 100. Each semiconductor material layer may be formed of different semiconductor materials and may be doped to different dopant concentrations. In embodiments in which the epitaxial source/drain regions 100 comprise three semiconductor material layers, the first semiconductor material layer may be deposited, the second semiconductor material layer may be deposited over the first semiconductor material layer, and the third semiconductor material layer may be deposited over the second semiconductor material layer. In some embodiments, the first semiconductor material layer may have a dopant concentration less than the second semiconductor material layer and greater than the third semiconductor material layer. Other semiconductor material layers, dopant concentrations, or configurations thereof are possible.

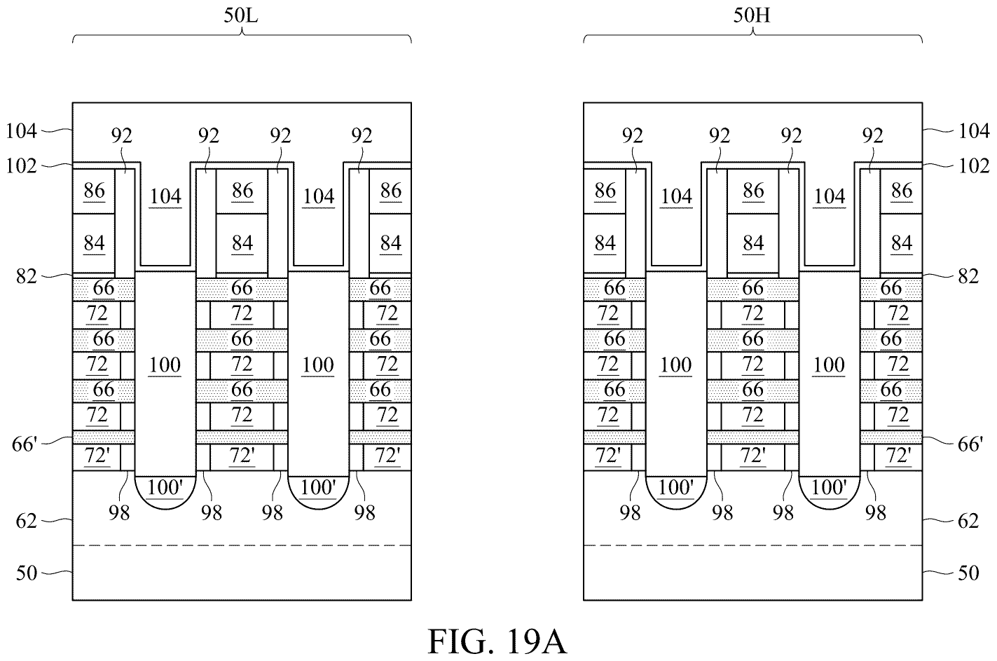

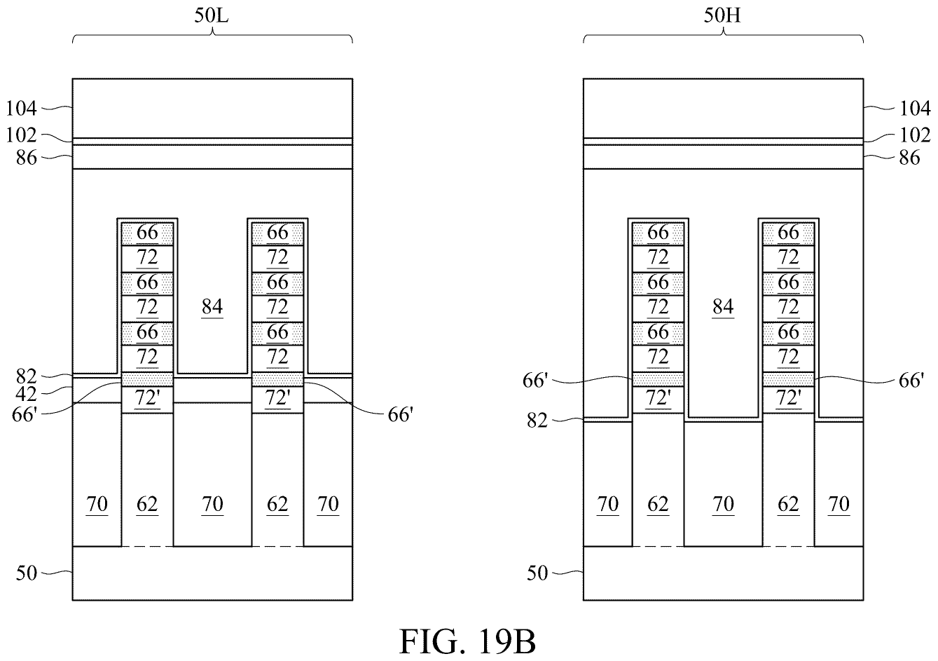

In FIGS. 19A-19B, a first ILD 104 is deposited over the epitaxial source/drain regions 100, the fin spacers 94, the gate spacers 92, the masks 86 (if present), and/or the dummy gates 84. The first ILD 104 may be formed of a dielectric material, which may be deposited by any suitable method, such as CVD, plasma-enhanced CVD (PECVD), or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 102 is formed between the first ILD 104 and the epitaxial source/drain regions 100, the fin spacers 94, the gate spacers 92, the masks 86 (if present), and/or the dummy gates 84. The CESL 102 may be formed of a dielectric material having a high etching selectivity from the etching of the first ILD 104, such as silicon nitride, silicon oxide, silicon oxynitride, a combination thereof, or the like, which may be formed using any suitable deposition process, such as CVD, ALD, or the like.

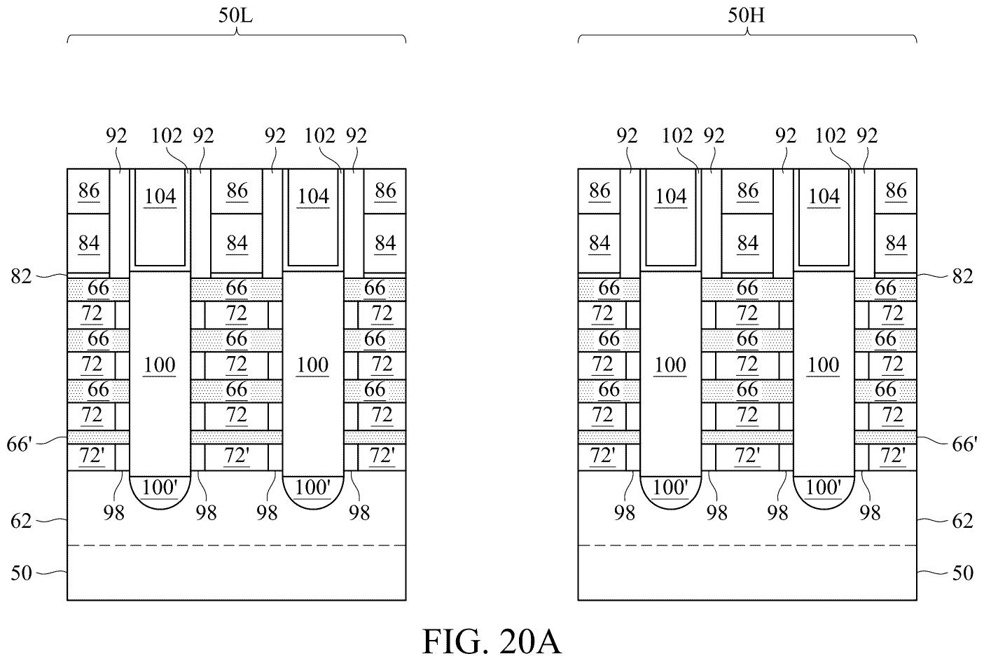

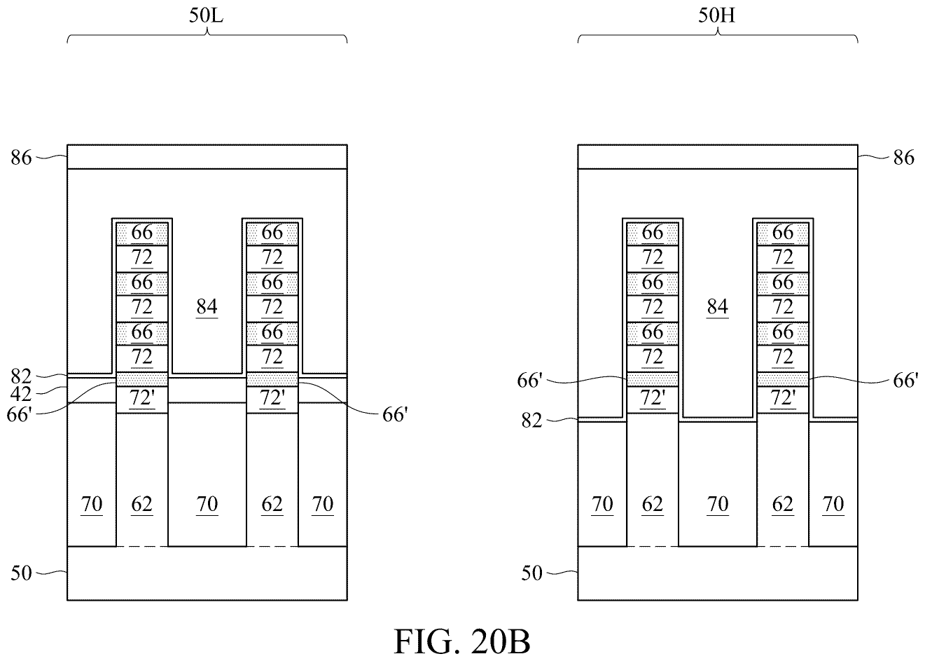

In FIGS. 20A-20B, a removal process is performed to level the top surfaces of the first ILD 104 with the top surfaces of the gate spacers 92 and the masks 86 (if present) or the dummy gates 84. In some embodiments, the removal process comprises a planarization process such as a chemical mechanical polish (CMP), a grinding process, an etch-back process, a combination thereof, or the like. After the planarization process, top surfaces of the first ILD 104, the gate spacers 92, the masks 86 (if present), and/or the dummy gates 84 may be substantially level or coplanar (within process variations). Accordingly, the top surfaces of the masks 86 (if present) or the dummy gates 84 may be exposed through the first ILD 104. In some embodiments, the planarization process removes the masks 86 and portions of the gate spacers 92 along sidewalls of the masks 86. In such embodiments, after the planarization process, top surfaces of the first ILD 104, the gate spacers 92, and the dummy gates 84 may be substantially level or coplanar (within process variations).

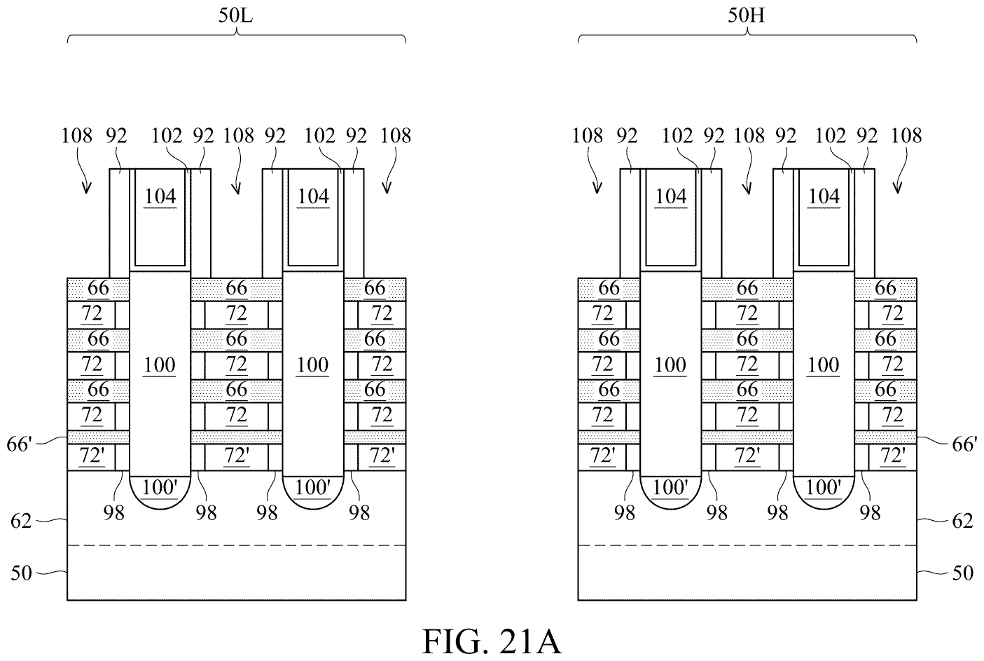

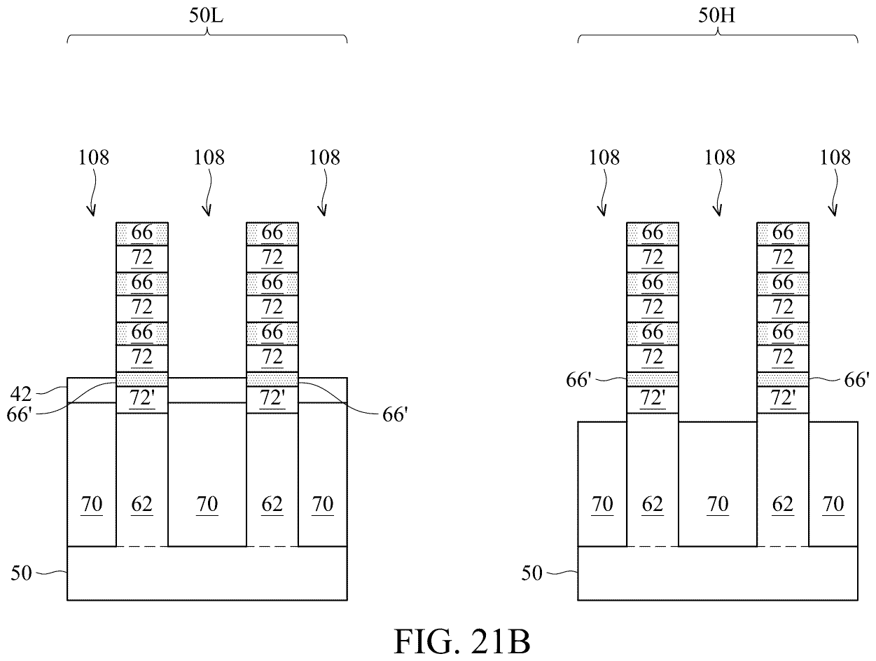

In FIGS. 21A-21B, the masks 86 (if present) and the dummy gates 84 are removed in one or more etching steps, such that recesses 108 are formed between the gate spacers 92. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 104 and the gate spacers 92. Each recess 108 exposes and/or overlies portions of nanostructures 66, which act as the channel regions in subsequently completed nanostructure-FETs. Portions of the nanostructures 66 which act as the channel regions are disposed between neighboring pairs of the epitaxial source/drain regions 100. During the removal, the dummy dielectrics 82 may be used as etch stop layers when the dummy gates 84 are etched. The dummy dielectrics 82 may then be removed after the removal of the dummy gates 84.

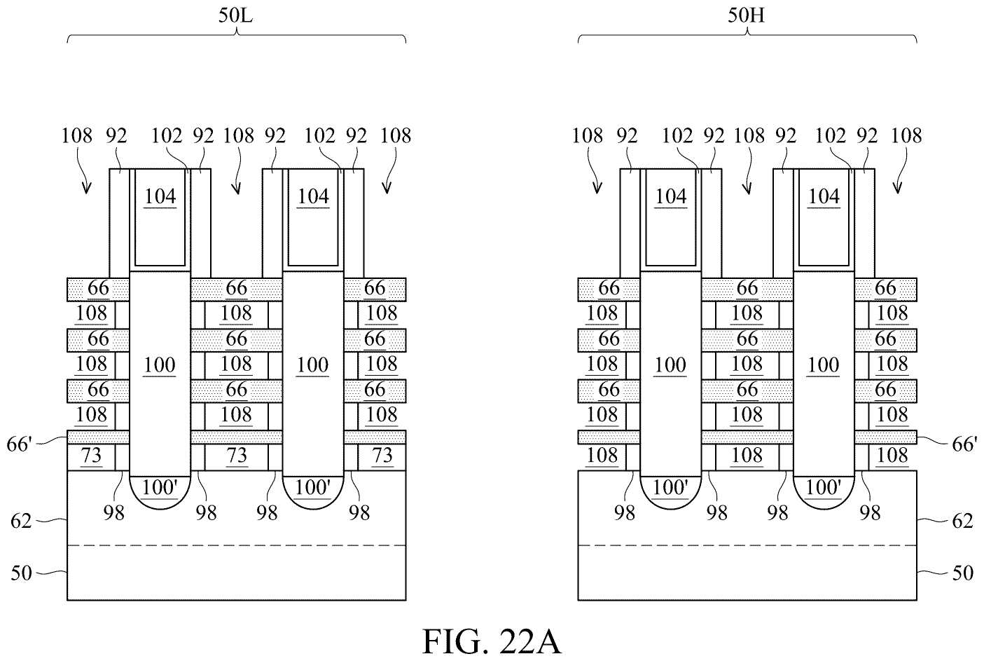

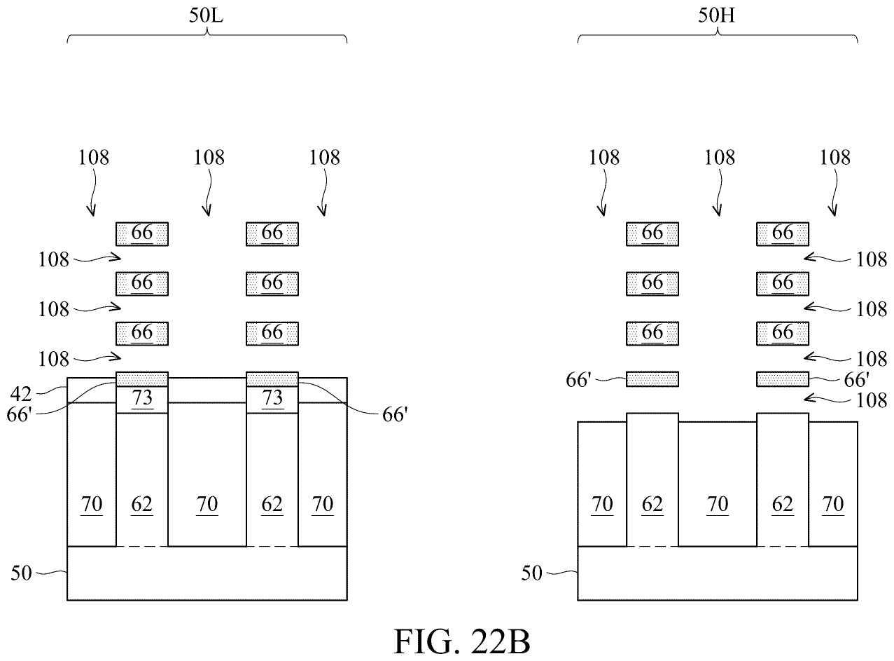

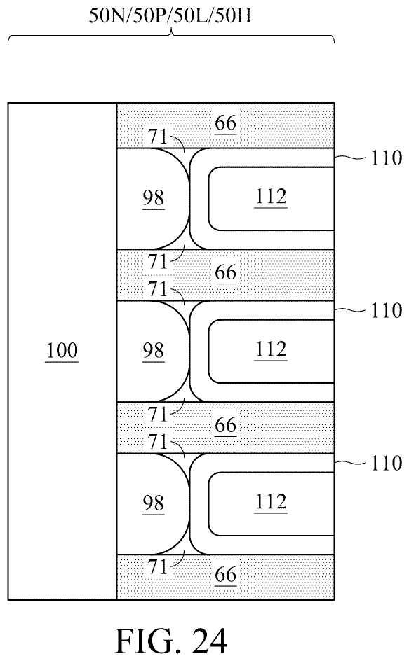

In FIGS. 22A-22B, the dummy regions 72 are removed, extending the recesses 108. The bottom dummy regions 72′ in the lower power region 50L are not removed and form dummy gate regions 73, described in greater detail below. Removing the dummy regions 72 may include performing an isotropic etching process such as wet etching or the like. The etching process may use etchants which are selective to the materials of the dummy regions 72, while the nanostructures 66 remain relatively unetched as compared to the dummy regions 72. The dummy regions 72 may be completely removed, or a residue of the dummy regions 72 may remain on some sidewall portions of the inner spacers 98 in the recesses 108 (see e.g., FIG. 24).

In some embodiments, the STI regions 70 in the higher power region 50H may be etched while removing the dummy regions 72, but the total amount of loss in the STI regions 70 may be reduced by controlling etching parameters (e.g., timing) while removing the dummy regions 72.

The protective layer 42 in the lower power region 50L may protect the STI regions 70 from etching during removal of the dummy regions 72. For embodiments in which a protective layer 42 remains over the STI regions 70 in the higher power region 50H (e.g., as in FIG. 9B), the STI regions 70 in the higher power region 50H may be protected from etching by the protective layer 42.

As described previously, the sidewalls of the bottom dummy regions 72′ in the lower power region 50L are covered by the inner spacers 98 the protective layer 42. The top surfaces of the bottom dummy regions 72′ are covered by the bottom nanostructures 66′, and the bottom surfaces of the bottom dummy regions 72′ are covered by the top surfaces of the fins 62. Accordingly, the bottom dummy regions 72′ in the lower power region 50L are protected from the etching process that removes the overlying dummy regions 72. Removing or thinning the protective layer 42 in the higher power region 50H to expose the bottom nanostructures 64′ (see FIGS. 8-9B) allows for the subsequent removal of the bottom dummy regions 72′ in the higher power region 50H. In this manner, the etching process removes dummy regions 72 including the bottom dummy regions 72′ in the higher power region 50H, but does not remove the bottom dummy regions 72′ in the lower power region 50L. The remaining bottom dummy regions 72′ in the lower power region 50L are subsequently referred to as dummy gate regions 73. In some cases, the dummy gate regions 73 may be considered bottom channel oxide regions, dummy nanostructures, isolation regions, or the like. The dummy gate regions 73 cover the bottom surfaces of the bottom nanostructures 66′ in the lower power region 50L, and thus the bottom channel regions of the bottom nanostructures 66′ are not controlled by an underlying gate structure in the subsequently formed nanostructure-FETs, described in greater detail below.

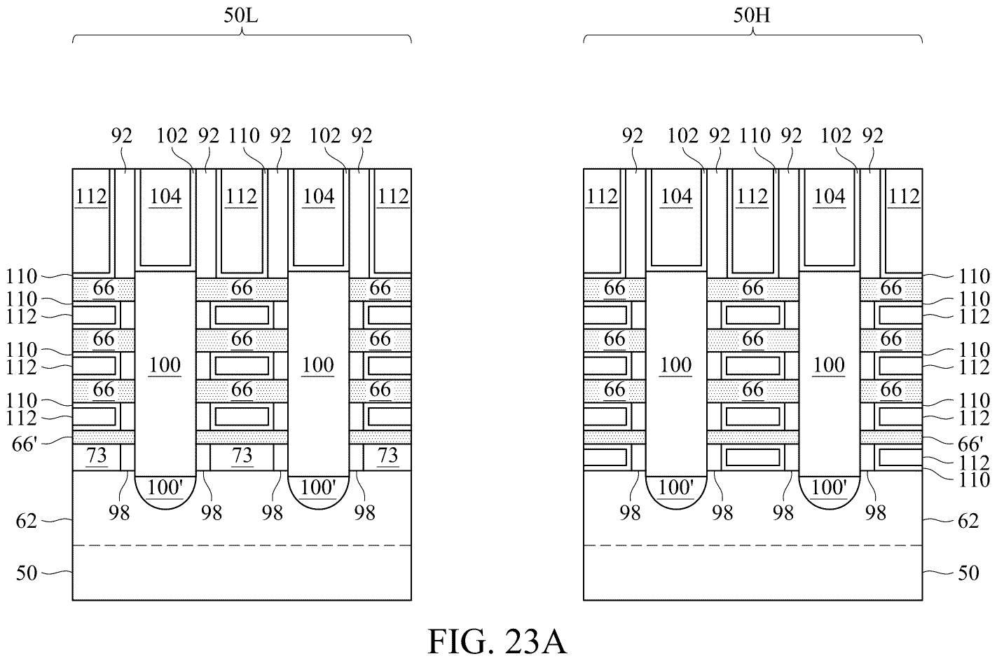

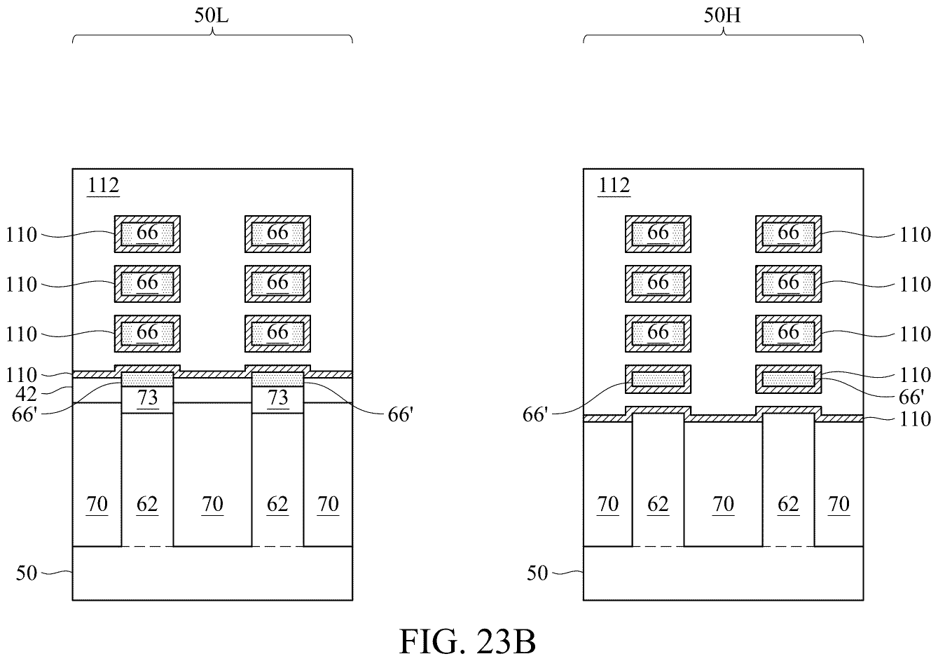

In FIGS. 23A-23B, gate dielectric layers 110 and gate electrodes 112 are formed for replacement gate structures. The gate dielectric layers 110 are deposited conformally in the recesses 108. The gate dielectric layers 110 may be formed on top surfaces and sidewalls of the substrate 50 and on exposed top surfaces, sidewalls, and bottom surfaces of the nanostructures 66. However, the dummy gate regions 73 prevent gate dielectric layers 110 from being formed on the bottom surfaces of the bottom nanostructures 66′ in the lower power region 50L. The gate dielectric layers 110 may also be deposited on top surfaces of the first ILD 104, the CESL 102, the gate spacers 92, the protective layer 42, and/or the STI regions 70. Because the dummy gate regions 73 are fully covered, the gate dielectric layers 110 are not formed on the dummy gate regions 73 and do not physically contact the dummy gate regions 73. In some cases, bottom surfaces of the dummy gate regions 73 in the lower power region 50L may be approximately level with bottom surfaces of the gate structures in the higher power region 50H.

In accordance with some embodiments, the gate dielectric layers 110 comprise one or more dielectric layers, such as an oxide, a metal oxide, the like, or combinations thereof. For example, in some embodiments, the gate dielectric layers 110 may comprise a silicon oxide layer and a metal oxide layer over the silicon oxide layer. In some embodiments, the gate dielectric layers 110 include a high-k dielectric material, and in these embodiments, the gate dielectric layers 110 may have a k value greater than about 7.0, and may include a metal oxide or a silicate of hafnium, aluminum, zirconium, lanthanum, manganese, barium, titanium, lead, and combinations thereof. The structure of the gate dielectric layers 110 may be the same or different in the n-type region 50N and the p-type region 50P. The formation methods of the gate dielectric layers 110 may include molecular-beam deposition (MBD), ALD, PECVD, and the like.

The gate electrodes 112 are deposited over the gate dielectric layers 110, respectively, and fill the remaining portions of the recesses 108. The gate electrodes 112 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 112 are illustrated in FIGS. 23A-23B, the gate electrodes 112 may comprise any number of liner layers, any number of work function tuning layers, and a fill material. Any combination of the layers which make up the gate electrodes 112 may be deposited between adjacent ones of the nanostructures 66 in the lower power region 50L and the higher power region 50H, and between the bottom nanostructures 66′ and the fins 62 in the higher power region 50H.

The formation of the gate dielectric layers 110 in the n-type region 50N and the p-type region 50P may occur simultaneously such that the gate dielectric layers 110 in each region are formed from the same materials, and the formation of the gate electrodes 112 may occur simultaneously such that the gate electrodes 112 in each region are formed from the same materials. In some embodiments, the gate dielectric layers 110 in each region may be formed by distinct processes, such that the gate dielectric layers 110 may be different materials and/or have a different number of layers, and/or the gate electrodes 112 in each region may be formed by distinct processes, such that the gate electrodes 112 may be different materials and/or have a different number of layers. Various masking steps may be used to mask and expose appropriate regions when using distinct processes.

After the filling of the recesses 108, a planarization process, such as a CMP, may be performed to remove the excess portions of the gate dielectric layers 110 and the material of the gate electrodes 112, which excess portions are over the top surface of the first ILD 104. The remaining portions of material of the gate electrodes 112 and the gate dielectric layers 110 thus form replacement gate structures of the resulting nano-FETs. The gate electrodes 112 and the gate dielectric layers 110 may be collectively referred to as gate structures or gate stacks.

In the lower power region 50L, the bottom-most gate structure under the bottom nanostructures 66′ is not formed due to the presence of the dummy gate regions 73. In other words, only upper portions of the bottom nanostructures 66′ in the lower power region 50L are covered by a gate structure. Because the bottom nanostructures 66′ in the higher power region 50H are fully surrounded by a gate structure but the bottom nanostructures 66′ in the lower power region 50L are only partially covered by a gate structure, the bottom nanostructures 66′ in the higher power region 50H provide more on-current than the bottom nanostructures 66′ in the lower power region 50L. Accordingly, the nanostructure-FETs in the lower power region 50L are lower power (e.g. lower current) devices than the nanostructure-FETs in the higher power region 50H. In this manner, both higher power nanostructure-FETs and lower power nanostructure FETs may be formed in different regions on the same substrate with only minor alterations to existing process flows. Additionally, the use of dummy gate regions 73 in lower power regions 50L allow for the formation of lower power nanostructure-FETs having reduced parasitic capacitance and improved AC performance.

In some cases, because only the upper portions of the bottom nanostructures 66′ in the lower power region 60 are covered by a gate structure, the bottom nanostructures 66′ in the lower power region 50L may be referred to as “half-nanostructures. ” Accordingly, the nanostructure-FETs in the higher power region 50H of FIGS. 23A-23B may be considered having nanostructure stacks with 4 nanostructures, but the nanostructure-FETs in the lower power region 50L of FIGS. 23A-23B may be considered having nanostructure stacks with 3.5 nanostructures. The techniques described herein allow nanostructure-FETs to be formed having may have any suitable number of nanostructures in a nanostructure stack. For example, a higher power nanostructure-FET may have 2 nanostructures or 3 nanostructures in a nanostructure stack, with the corresponding lower power nanostructure-FET having 1.5 nanostructures or 2.5 nanostructures in a nanostructure stack, respectively. Other numbers of nanostructures in a nanostructure stack are possible. It should be noted that number of nanostructures in a nanostructure stack (e.g., 1.5, 2, 3.5, 4, etc.) may or may not be approximately proportional to the on-current produced by the corresponding nanostructure-FET.

FIG. 24 illustrates a detailed view of various elements of FIG. 23A, including the epitaxial source/drain regions 100, the gate dielectric layers 110, the gate electrodes 112, the nanostructures 66, and the inner spacers 98. The view of FIG. 24 may be a magnified view of a portion of a nanostructure-FET in any of the n-type region 50N, p-type region 50P, lower power region 50L, or higher power region 50H. In some embodiments, illustrated by FIG. 24, a residue of the dummy material 71 may remain on the inner spacers 98, such as between the inner spacers 98 and the gate dielectric layers 110. For example, the dummy regions 72 may not be fully removed, and the gate dielectric layers 110 may be formed on the remaining dummy material 71 of the dummy regions 72. Because the dummy material 71 is an insulating material (e.g., silicon oxide or the like), the remaining residue may not significantly impact the electrical performance of the resulting device.

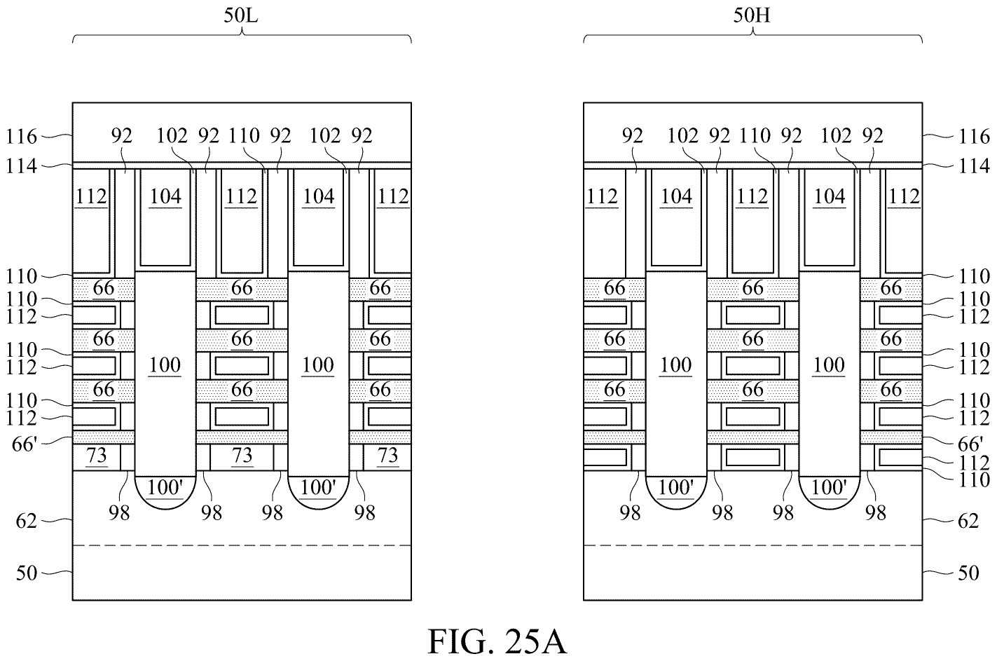

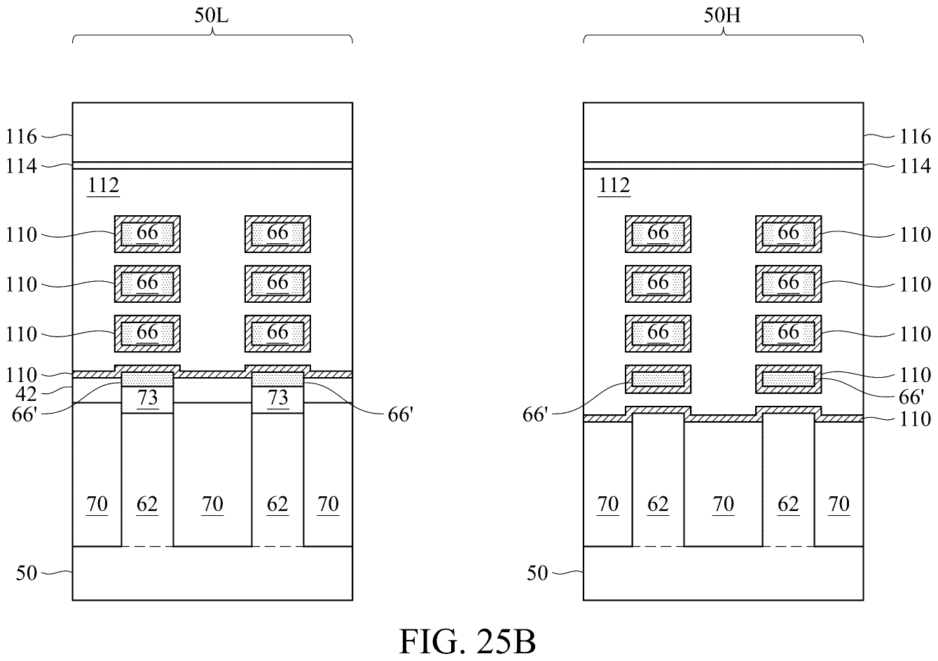

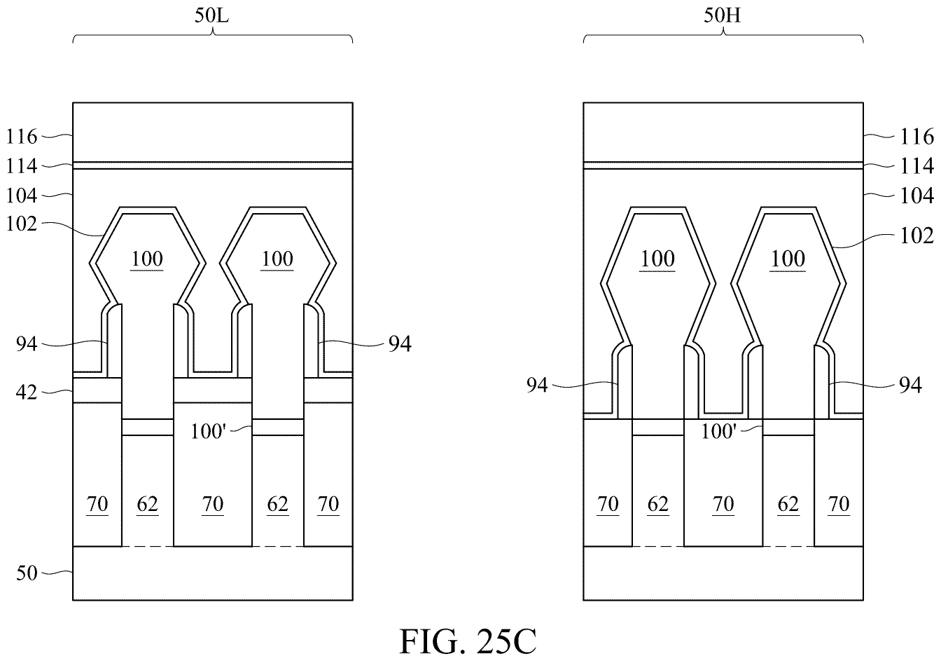

In FIGS. 25A-25C, a second ILD 116 is deposited over the gate spacers 92, the CESL 102, the first ILD 104, the gate dielectric layers 110, and the gate electrodes 112, in accordance with some embodiments. In some embodiments, the second ILD 116 is a flowable film formed by a flowable CVD method. In some embodiments, the second ILD 116 is formed of a dielectric material such as PSG, BSG, BPSG, USG, or the like, which may be formed by any suitable deposition process, such as CVD, PECVD, or the like.

In some embodiments, an etch stop layer (ESL) 114 is formed between the second ILD 116 and the gate spacers 92, the CESL 102, the first ILD 104, the gate dielectric layers 110, and the gate electrodes 112.

The ESL 114 may be formed of a dielectric material having a high etching selectivity from the etching of the second ILD 116, such as silicon nitride, silicon oxide, silicon oxynitride, or the like, which may be formed by any suitable deposition process, such as CVD, ALD, or the like.

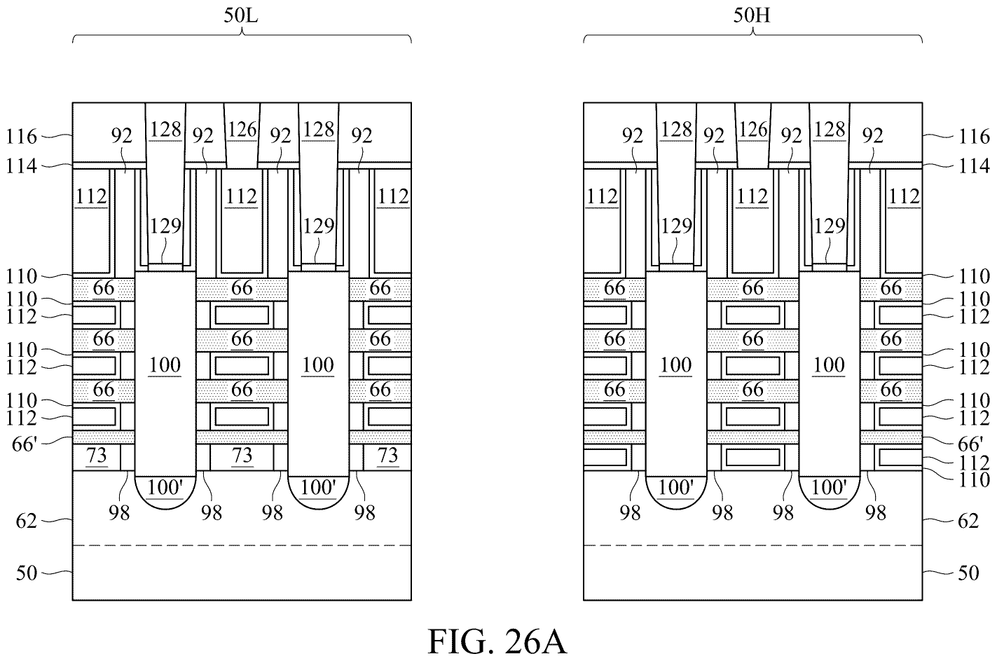

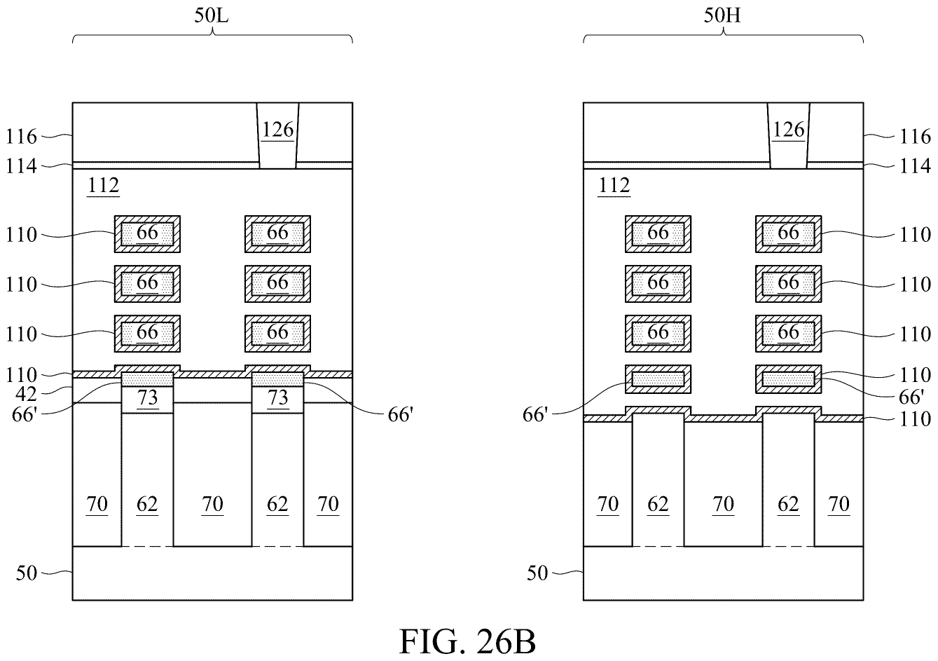

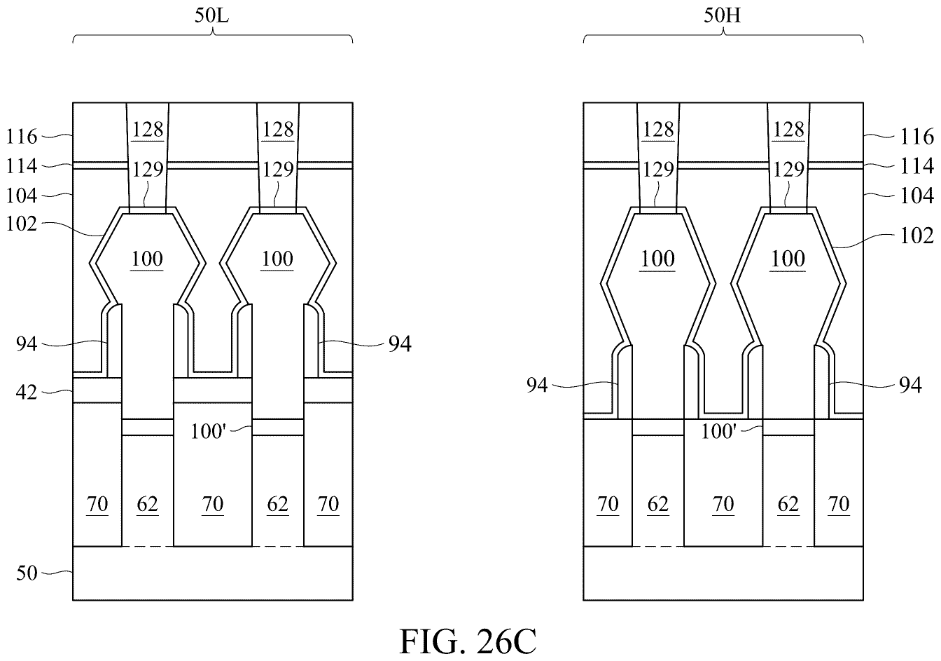

In other embodiments, the gate structure (including the gate dielectric layers 110 and the corresponding overlying gate electrodes 112) is recessed, so that a recess is formed directly over the gate structure and between opposing portions of gate spacers 92. A gate mask (not separately illustrated) comprising one or more layers of dielectric material, such as silicon nitride, silicon oxynitride, or the like, may be filled in the recess, followed by a planarization process to remove excess portions of the dielectric material extending over the first ILD 104. Subsequently formed gate contacts (such as the gate contacts 126, discussed below with respect to FIGS. 26A-26C) penetrate through the gate mask to contact the top surface of the recessed gate electrodes 112.

In FIGS. 26A-26C, gate contacts 126 and source/drain contacts 128 are formed to contact, respectively, the gate electrodes 112 and the source/drain regions 100. The gate contacts 126 may be physically and electrically coupled to the gate electrodes 112. The source/drain contacts 128 may be physically and electrically coupled to the source/drain regions 100.

As an example of forming the gate contacts 126 and the source/drain contacts 128, openings for the gate contacts 126 are formed through the second ILD 116 and the ESL 114, and openings for the source/drain contacts 128 are formed through the second ILD 116, the ESL 114, the first ILD 104, and the CESL 102. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 116. The remaining liner and conductive material form the gate contacts 126 and the source/drain contacts 128 in the openings. The gate contacts 126 and the source/drain contacts 128 may be formed in distinct processes, or may be formed in the same process. Although shown as being formed in the same cross-sections, it should be appreciated that each of the gate contacts 126 and the source/drain contacts 128 may be formed in different cross-sections, which may avoid shorting of the contacts.

Optionally, metal-semiconductor alloy regions 129 are formed at the interfaces between the source/drain regions 100 and the source/drain contacts 128. The metal-semiconductor alloy regions 129 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 129 can be formed before the material(s) of the source/drain contacts 128 by depositing a metal in the openings for the source/drain contacts 128 and then performing a thermal annealing process. The metal can be any metal capable of reacting with the semiconductor materials (e.g., silicon, silicon carbide, silicon germanium, germanium, etc.) of the source/drain regions 100 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 128, such as from surfaces of the metal-semiconductor alloy regions 129. The material(s) of the source/drain contacts 128 can then be formed on the metal-semiconductor alloy regions 129.

Embodiments may achieve advantages. The techniques described herein allow for the formation of lower power nanostructure-FETs and higher performance nanostructure-FETs on the same substrate (e.g., on the same wafer). The techniques described herein allow for the formation of lower power and higher power nanostructure-FETs within the same chip or die without expensive or time-consuming chiplet packaging processes. The techniques described herein may form a “hybrid nanostructure” device comprising relatively lower power nanostructure-FETs and relatively higher power nanostructure-FETs. The techniques described herein can form a hybrid nanostructure device using a more reliable process flow and with fewer additional process steps needed. The lower power nanostructure-FETs described herein include an insulating dummy gate structure at least partially covering a nanostructure's channel region. This allows for the formation of a lower power nanostructure having smaller parasitic capacitance, which can improve speed and AC performance of the corresponding nanostructure-FET. For example, the higher power nanostructure-FETs can be used for higher power or high-performance applications and the lower power nanostructure-FETs can be used for lower power or high-speed applications. Other applications, devices, or configurations are possible.

In an embodiment of the present disclosure, a device includes a first semiconductor fin and a second semiconductor fin; a first nanostructure over the first semiconductor fin; a second nanostructure over the second semiconductor fin; a dummy region extending between the first semiconductor fin and a bottom surface of the first nanostructure; and a gate structure on a top surface of the first nanostructure, on a top surface of the second nanostructure, and extending between the second semiconductor fin and a bottom surface of the second nanostructure. In an embodiment, the dummy region is an oxide material. In an embodiment, the dummy region is free of physical contact with the gate structure. In an embodiment, the device includes an isolation region surrounding the first semiconductor fin; and a protective layer on the isolation region, wherein the protective layer extends along a sidewall of the dummy region and along a sidewall of the first nanostructure. In an embodiment, sidewalls of the second nanostructure are free of physical contact with the protective layer. In an embodiment, the gate structure extends on a top surface of the protective layer. In an embodiment, the device includes a source/drain region in the first semiconductor fin, wherein a bottom surface of the source/drain region is lower than a top surface of the dummy region. In an embodiment, the device includes a gate spacer on the first semiconductor fin, wherein the gate spacer extends along a sidewall of the dummy region.

In an embodiment of the present disclosure, a device includes a first fin and a second fin over a semiconductor substrate; first nanostructures over the first fin; second nanostructures over the second fin; a dielectric region over the first fin, wherein the dielectric region separates the plurality of first nanostructures from the first fin; a first gate structure over the first fin, wherein the first gate structure separates respectively adjacent first nanostructures; and a second gate structure over the second fin, wherein the second gate structure separates the second nanostructures from the second fin, wherein the second gate structure separates respectively adjacent second nanostructures. In an embodiment, the device includes a first shallow trench isolation (STI) region surrounding the first fin; a second STI region surrounding the second fin; and a first hard mask on the first STI region. In an embodiment, the device includes a second hard mask on the second STI region, wherein the second hard mask is thinner than the first hard mask. In an embodiment, the first hard mask is a nitride material. In an embodiment, a top surface of the second STI region is closer to the semiconductor substrate than a top surface of the first STI region. In an embodiment, a bottom surface of the bottom-most first nanostructure is free of physical contact with the first gate structure. In an embodiment, the number of first nanostructures is the same as the number of second nanostructures. In an embodiment, a bottom surface of the second gate structure is closer to the semiconductor substrate than a bottom surface of the first gate structure.

In an embodiment of the present disclosure, a method includes forming a first fin and a second fin over a semiconductor substrate; forming first nanostructures over the first fin and second nanostructures over the second fin; depositing a dielectric material on the first fin, the second fin, the first nanostructures, and the second nanostructures; etching the dielectric material to form a first dummy gate region on the first fin, a second dummy gate region on the second fin, first dummy nanostructures between ones of the first nanostructures, and second dummy nanostructures between ones of the second nanostructures; performing an etching process to remove the first dummy nanostructures, the second dummy nanostructures, and the second dummy gate region, wherein the first dummy gate region remains on the first fin after performing the etching process; and depositing gate structure layers on the second fin, the first nanostructures, and the second nanostructures. In an embodiment, the method includes forming a first isolation region surrounding the first fin and a second isolation region surrounding the second fin; forming a protective layer on the first isolation region and on the second isolation region; and removing the protective layer from the second isolation region. In an embodiment, the method includes forming gate spacers on sidewalls of the first dummy gate region. In an embodiment, the first dummy gate region covers a bottom surface of a first nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein.

Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first semiconductor fin and a second semiconductor fin;
a first nanostructure over the first semiconductor fin;
a second nanostructure over the second semiconductor fin;
a dummy region extending between the first semiconductor fin and a bottom surface of the first nanostructure; and
a gate structure on a top surface of the first nanostructure, on a top surface of the second nanostructure, and extending between the second semiconductor fin and a bottom surface of the second nanostructure.

2. The device of claim 1, wherein the dummy region comprises an oxide material.

3. The device of claim 1, wherein the dummy region is free of physical contact with the gate structure.

4. The device of claim 1 further comprising:
an isolation region surrounding the first semiconductor fin; and
a protective layer on the isolation region, wherein the protective layer extends along a sidewall of the dummy region and along a sidewall of the first nanostructure.

5. The device of claim 4, wherein sidewalls of the second nanostructure are free of physical contact with the protective layer.

6. The device of claim 4, wherein the gate structure extends on a top surface of the protective layer.

7. The device of claim 1 further comprising a source/drain region in the first semiconductor fin, wherein a bottom surface of the source/drain region is lower than a top surface of the dummy region.

8. The device of claim 1, further comprising a gate spacer on the first semiconductor fin, wherein the gate spacer extends along a sidewall of the dummy region.

9. A device comprising:
a first fin and a second fin over a semiconductor substrate;
a plurality of first nanostructures over the first fin;
a plurality of second nanostructures over the second fin;
a dielectric region over the first fin, wherein the dielectric region separates the plurality of first nanostructures from the first fin;
a first gate structure over the first fin, wherein the first gate structure separates respectively adjacent first nanostructures of the plurality of first nanostructures; and
a second gate structure over the second fin, wherein the second gate structure separates the plurality of second nanostructures from the second fin, wherein the second gate structure separates respectively adjacent second nanostructures of the plurality of second nanostructures.

10. The device of claim 9 further comprising:
a first shallow trench isolation (STI) region surrounding the first fin;
a second STI region surrounding the second fin; and
a first hard mask on the first STI region.

11. The device of claim 10 further comprising a second hard mask on the second STI region, wherein the second hard mask is thinner than the first hard mask.

12. The device of claim 10, wherein the first hard mask comprises a nitride material.

13. The device of claim 10, wherein a top surface of the second STI region is closer to the semiconductor substrate than a top surface of the first STI region.

14. The device of claim 9, wherein a bottom surface of the bottom-most first nanostructure is free of physical contact with the first gate structure.

15. The device of claim 9, wherein the number of first nanostructures is the same as the number of second nanostructures.

16. The device of claim 9, wherein a bottom surface of the second gate structure is closer to the semiconductor substrate than a bottom surface of the first gate structure.

17. A method comprising:
forming a first fin and a second fin over a semiconductor substrate;
forming first nanostructures over the first fin and second nanostructures over the second fin;
depositing a dielectric material on the first fin, the second fin, the first nanostructures, and the second nanostructures;
etching the dielectric material to form a first dummy gate region on the first fin, a second dummy gate region on the second fin, first dummy nanostructures between ones of the first nanostructures, and second dummy nanostructures between ones of the second nanostructures;
performing an etching process to remove the first dummy nanostructures, the second dummy nanostructures, and the second dummy gate region, wherein the first dummy gate region remains on the first fin after performing the etching process; and
depositing gate structure layers on the second fin, the first nanostructures, and the second nanostructures.

18. The method of claim 17 further comprising:
forming a first isolation region surrounding the first fin and a second isolation region surrounding the second fin;
forming a protective layer on the first isolation region and on the second isolation region; and
removing the protective layer from the second isolation region.

19. The method of claim 17 further comprising forming gate spacers on sidewalls of the first dummy gate region.

20. The method of claim 17, wherein the first dummy gate region covers a bottom surface of a first nanostructure.
